(19) United States
(12) Patent Application Publication
(10) Pub. No.: US 2013/0273361 A1
(43) Pub. Date: Oct. 17, 2013

(54) Active Energy Ray-Curable Pressure-Sensitive Adhesive for Re-Release and Dicing Die-Bonding Film

(71) Applicant: NITTO DENKO CORPORATION, Osaka (JP)

(72) Inventors: Katsuhiko KAMIYA, Ibaraki-shi (JP); Tomokazu Takahashi, Ibaraki-shi (JP); Chie Kitano, Ibaraki-shi (JP); Mika Okada, Ibaraki-shi (JP); Takeshi Matsumura, Ibaraki-shi (JP); Shuhei Murata, Ibaraki-shi (JP); Hironao Otake, Ibaraki-shi (JP); Masatsugu Koso, Ibaraki-shi (JP)

(21) Appl. No.: 13/914,716

(22) Filed: Jun. 11, 2013

Related U.S. Application Data
(62) Division of application No. 13/176,205, filed on Jul. 5, 2011.

(30) Foreign Application Priority Data
Jul. 5, 2010 (JP) 2010-152699
Jul. 5, 2010 (JP) 2010-152700
Jul. 5, 2010 (JP) 2010-152701
Jul. 6, 2010 (JP) 2010-153635
Jul. 6, 2010 (JP) 2010-153636
Jul. 6, 2010 (JP) 2010-153637
Jul. 7, 2010 (JP) 2010-154448
Jul. 7, 2010 (JP) 2010-154449

(51) Int. Cl. H01L 21/683

(52) U.S. Cl. CPC H01L 21/6836
USPC 428/354

(57) ABSTRACT

Provided is an active energy ray-curable pressure-sensitive adhesive for re-release, which has a small influence on an environment or a human body, can be easily handled, can largely change its pressure-sensitive adhesiveness before and after irradiation with an active energy ray, and can express high pressure-sensitive adhesiveness before the irradiation with the active energy ray and express high releasability after the irradiation with the active energy ray. The active energy ray-curable pressure-sensitive adhesive for re-release includes an active energy ray-curable polymer (P), in which the polymer (P) includes one of a polymer obtained by causing a carboxyl group-containing polymer (P3) and an oxazoline group-containing monomer (m3) to react with each other, and a polymer obtained by causing an oxazoline group-containing polymer (P4) and a carboxyl group-containing monomer (m2) to react with each other.

This application is a divisional of application Ser. No. 13/176,205 filed Jul. 5, 2011, which claims priority based on Japanese Patent Application Nos. 2010-152699 filed Jul. 5, 2010, 2010-152700 filed Jul. 5, 2010, 2010-152701 filed Jul. 5, 2010, 2010-153635 filed Jul. 6, 2010, 2010-153636 filed Jul. 6, 2010, 2010153637 filed Jul. 6, 2010, 2010-154448 filed Jul. 7, 2010 and 2010-154449 filed Jul. 7, 2010; the contents of all of which are incorporated herein by reference in their entirety.

### BACKGROUND OF THE INVENTION

1. Field of the Invention

The present invention relates to an active energy ray-curable pressure-sensitive adhesive for re-release used for protecting surfaces, or preventing breakage, of processed parts such as semiconductors, circuits, various printed boards, various masks, and lead frames during their production, and more particularly, to an active energy ray-curable pressure-sensitive adhesive for re-release suitably used in a pressure-sensitive adhesive sheet for processing a semiconductor wafer used at the time of grinding of the backside of the semiconductor wafer or at the time of dicing of the wafer.

The present invention also relates to a dicing die-bonding film, and more specifically, to a dicing die-bonding film used in dicing of a workpiece (such as a semiconductor wafer), the film being capable of establishing such a state that an adhesive for securely fixing a chip-shaped workpiece (such as a semiconductor chip) and an electrode member has already been provided for a workpiece (such as a semiconductor wafer) before the dicing.

2. Description of the Related Art

A semiconductor wafer (workpiece) on which a circuit pattern has been formed is subjected to dicing into semiconductor chips (chip-shaped workpieces) (dicing step) after the thickness of the wafer has been adjusted by backside polishing as required. In the dicing step, the semiconductor wafer is generally washed at a moderate liquid pressure (typically about 2 kg/cm²) in order that a cutting layer may be removed. Next, the semiconductor chips subjected to the dicing described above are securely fixed to an adherend such as a lead frame with an adhesive (mounting step). Subsequently, the semiconductor chips securely fixed to the adherend described above are subjected to bonding (bonding step).

In the above-mentioned mounting step, the above-mentioned adhesive is applied to the surface of the lead frame or of each of the semiconductor chips. However, the application of the adhesive involves such a problem that a special apparatus is needed or that the work requires a long time period. In addition, the following problem arises. It is difficult to level an adhesive layer owing to the nature of the application work.

To solve such problems as described above, the following dicing die-bonding film has been proposed (see, for example, Japanese Patent Application Laid-open No. Sho 60-57642). The semiconductor wafer can be bonded and retained onto the dicing die-bonding film in the dicing step, and the film can provide an adhesive layer for securely fixing to the adherend in the mounting step.

The dicing die-bonding film described in Japanese Patent Application Laid-open No. Sho 60-57642 is obtained by providing the adhesive layer on a supporting base material in a releasable manner. That is, the semiconductor wafer is subjected to dicing while being retained by the adhesive layer, and then the supporting base material is stretched. The semiconductor chips are released together with the adhesive layer, and are then individually collected. The collected semiconductor chips each provided with the adhesive layer are securely fixed to an adherend such as a lead frame through the adhesive layer.

Such adhesive layer of the dicing die-bonding film as described above is demanded to have good retention for the semiconductor wafer lest an inability in dicing, a dimensional mistake, or the like should occur, and good releasability with which the semiconductor chips after the dicing can be released from the supporting base material together with the adhesive layer.

However, there arises such a problem that it is difficult to express both of the above-mentioned characteristics, that is, the good retention and the good releasability in a balanced manner. In particular, when large retention is requested of the adhesive layer like, for example, a mode in which the semiconductor wafer is subjected to dicing with a rotary round blade or the like, it is difficult to obtain a dicing die-bonding film capable of expressing both of the above-mentioned characteristics in a balanced manner.

To solve such problem as described above, various methods of improving a dicing die-bonding film have been proposed (see, for example, Japanese Patent Application Laid-open No. Hei 2-248064).

In a dicing die-bonding film described in Japanese Patent Application Laid-open No. Hei 2-248064, a UV-curable pressure-sensitive adhesive layer is interposed between a supporting base material and an adhesive layer. Curing the pressure-sensitive adhesive layer with UV light after dicing reduces an adhesive strength between the pressure-sensitive adhesive layer and the adhesive layer. The reduction in the adhesive strength improves the ease with which the pressure-sensitive adhesive layer and the adhesive layer are released from each other, and facilitates the pickup of a semiconductor chip.

However, it is still difficult to obtain a dicing die-bonding film capable of expressing good retention at the time of the dicing and good releasability thereafter in a balanced manner even by the above-mentioned improving method. In, for example, the case where a large semiconductor chip measuring 10 mm or more by 10 mm or more is to be obtained, it is not easy to pick up the semiconductor chip with a general die bonder because the area of the chip is large.

To solve such problem as described above, various methods of improving a dicing die-bonding film have additionally been proposed (see, for example, Japanese Patent Application Laid-open No. 2009-170786).

In a dicing die-bonding film described in Japanese Patent Application Laid-open No. 2009-170786, a pressure-sensitive adhesive obtained by causing a hydroxyl group in a polymer, and a compound having an isocyanate group that reacts with a hydroxyl group and a radical reactive carbon-carbon double bond to react with each other is used. The use of such pressure-sensitive adhesive facilitates the pickup of a semiconductor chip.

However, a tin-based catalyst is added for promoting the reaction between the isocyanate group-containing compound and the hydroxyl group-containing polymer in some cases, and in such cases, the following problem arises. An influence on an environment is large. In addition, there arises such a problem that the compound having an isocyanate group and a radical reactive carbon-carbon double bond reacts with water to deactivate. Further, sufficient attention must be paid to the dealing of the compound having an isocyanate group and a radical reactive carbon-carbon double bond because the compound is volatile and hence involves such a problem that an influence on an environment or a human body is large.

In addition, a semiconductor wafer formed of silicon, gallium, arsenic, or the like is produced in a large-diameter state, and then its backside is ground. Further, the wafer is cut and separated (subjected to dicing) into device chips. Further, the chips are transferred to a mounting step.

In the step of grinding the backside of the semiconductor wafer (backside-grinding step), a pressure-sensitive adhesive sheet obtained by applying a pressure-sensitive adhesive onto a base material formed of a plastic film is used for protecting the pattern surface of the semiconductor wafer.

In addition, various steps including dicing, washing, expanding, pickup, and mounting are added upon production of the device chips and in the mounting step. The pressure-sensitive adhesive sheet obtained by applying the pressure-sensitive adhesive onto the base material formed of the plastic film is used in a process commencing on the step of dicing the semiconductor wafer and ending on the pickup step as well.

In the backside-grinding step, the pressure-sensitive adhesive sheet is requested to sufficiently bond to the semiconductor wafer without peeling in order that the pattern surface of the semiconductor wafer may be protected. In addition, the sheet is requested to be more easily releasable than the semiconductor wafer is after the grinding.

In the dicing step, the cut and separated device chips are requested to be prevented from peeling off the pressure-sensitive adhesive sheet. That is, high pressure-sensitive adhesiveness is requested of the pressure-sensitive adhesive sheet. On the other hand, the cut and separated device chips must be easily released from the pressure-sensitive adhesive sheet in the pickup step. That is, low pressure-sensitive adhesiveness is requested of the pressure-sensitive adhesive sheet.

An active energy ray-curable pressure-sensitive adhesive for re-release is used for controlling the above-mentioned two contradictory pressure-sensitive adhesivenesses. The active energy ray-curable pressure-sensitive adhesive for re-release has such high pressure-sensitive adhesiveness that the device chips do not peel off the pressure-sensitive adhesive sheet before irradiation with an active energy ray. After the irradiation with the active energy ray, however, the pressure-sensitive adhesive cures to express such low pressure-sensitive adhesiveness that the device chips are easily released from the pressure-sensitive adhesive sheet.

An example in which an active energy ray-reactive polymer containing, in a molecular side chain thereof, a carbon-carbon double bond that is subjected to a reaction by an active energy ray is used has been reported as a conventional example of the active energy ray-curable pressure-sensitive adhesive for re-release (see, for example, Japanese Patent Application Laid-open No. 2000-355678). In Japanese Patent Application Laid-open No. 2000-355678, the active energy ray-curable pressure-sensitive adhesive for re-release is produced by causing a compound having an isocyanate group that reacts with a hydroxyl group and a radical reactive carbon-carbon double bond to react with an acrylic polymer having a hydroxyl group.

As described in the foregoing, however, a tin-based catalyst is added for promoting the reaction between the isocyanate group-containing compound and the hydroxyl group-containing polymer in some cases, and in such cases, the following problem arises. An influence on an environment is large. In addition, there arises such a problem that the compound having an isocyanate group and a radical reactive carbon-carbon double bond reacts with water to deactivate. Further, sufficient attention must be paid to the dealing of the compound having an isocyanate group and a radical reactive carbon-carbon double bond because the compound is volatile and hence involves such a problem that an influence on an environment or a human body is large.

In addition, the reaction between the acrylic polymer having a hydroxyl group, and the compound having an isocyanate group that reacts with a hydroxyl group and a radical reactive carbon-carbon double bond cannot be performed in an aqueous system because the isocyanate group reacts with water to deactivate.

The adoption of a block isocyanate group instead of an isocyanate group is given as means for performing such reaction as described above in an aqueous system (see, for example, Japanese Patent Application Laid-open No. 2008-19341).

However, a reaction between the acrylic polymer having a hydroxyl group, and a compound having a block isocyanate group and a radical reactive carbon-carbon double bond is slow, and the compound is problematic in terms of its handling and the like.

### SUMMARY OF THE INVENTION

An object of the present invention is to provide an active energy ray-curable pressure-sensitive adhesive for re-release, which has a small influence on an environment or a human body, can be easily handled, can largely change its pressure-sensitive adhesiveness before and after irradiation with an active energy ray, and can express high pressure-sensitive adhesiveness before the irradiation with the active energy ray and express high releasability after the irradiation with the active energy ray.

Another object of the present invention is to provide a dicing die-bonding film having, on a base material, a dicing film having a pressure-sensitive adhesive layer and a die-bonding film provided on the pressure-sensitive adhesive layer, the dicing die-bonding film having the following features: (1) the film can express good retention for a semiconductor wafer upon its dicing, and good releasability with which semiconductor chips after the dicing can be released from the base material together with the die-bonding film in a balanced manner irrespective of the sizes and thicknesses of the semiconductor wafer and the semiconductor chips, (2) the film has a small influence on an environment or a human body, and (3) the film can be easily handled.

An active energy ray-curable pressure-sensitive adhesive for re-release according to the present invention includes an active energy ray-curable polymer (P), in which the polymer (P) includes one of a polymer obtained by causing a carboxyl group-containing polymer (P3) and an oxazoline group-containing monomer (m3) to react with each other, and a polymer obtained by causing an oxazoline group-containing polymer (P4) and a carboxyl group-containing monomer (m2) to react with each other.

In a preferred embodiment, the above-mentioned carboxyl group-containing polymer (P3) includes a polymer (P1) constructed of monomer components containing an acrylic acid ester (m1) as a main monomer and the carboxyl group-containing monomer (m2).

In a preferred embodiment, the above-mentioned oxazoline group-containing polymer (P4) includes a polymer (P2) constructed of monomer components containing an acrylic acid ester (m1) as a main monomer and the oxazoline group-containing monomer (m3).

In a preferred embodiment, the above-mentioned carboxyl group-containing monomer (m2) includes at least one kind selected from the group consisting of (meth)acrylic acid and a carboxyalkyl (meth)acrylate.

In a preferred embodiment, the above-mentioned oxazoline group-containing monomer (m3) includes at least one kind selected from the group consisting of 2-vinyl-2-oxazoline, 4-methyl-2-vinyl-2-oxazoline, 5-methyl-2-vinyl-2-oxazoline, 2-vinyl-4,4-dimethyl-2-oxazoline, 2-isopropenyl-2-oxazoline, 4-methyl-2-isopropenyl-2-oxazoline, 5-methyl-2-isopropenyl-2-oxazoline, and 2-isopropenyl-4,4-dimethyl-2-oxazoline.

In a preferred embodiment, the above-mentioned polymer (P) has a glass transition temperature of −70° C. to −10° C.

In a preferred embodiment, the above-mentioned carboxyl group-containing polymer (P3) is a water dispersion.

In a preferred embodiment, the above-mentioned water dispersion is synthesized with a reactive emulsifier having a radical polymerizable functional group.

In a preferred embodiment, the above-mentioned oxazoline group-containing polymer (P4) is a water dispersion.

In a preferred embodiment, the above-mentioned water dispersion is synthesized with a reactive emulsifier having a radical polymerizable functional group.

The active energy ray-curable pressure-sensitive adhesive tape or sheet for re-release according to the present invention includes: a base material; and the active energy ray-curable pressure-sensitive adhesive for re-release according to the present invention as a pressure-sensitive adhesive layer on the base material.

In a preferred embodiment, the active energy ray-curable pressure-sensitive adhesive tape or sheet for re-release according to the present invention is used for processing a semiconductor wafer.

A dicing die-bonding film according to the present invention includes: a base material; a dicing film having a pressure-sensitive adhesive layer on the base material; and a die-bonding film provided on the pressure-sensitive adhesive layer, in which: the pressure-sensitive adhesive layer contains one of the active energy ray-curable pressure-sensitive adhesive for re-release according to the present invention and a cured product of the pressure-sensitive adhesive; and the die-bonding film contains an epoxy resin.

According to the present invention, there can be provided the active energy ray-curable pressure-sensitive adhesive for re-release, which has a small influence on an environment or a human body, can be easily handled, can largely change its pressure-sensitive adhesiveness before and after irradiation with an active energy ray, and can express high pressure-sensitive adhesiveness before the irradiation with the active energy ray and express high releasability after the irradiation with the active energy ray.

In addition, according to the present invention, there can be provided the dicing die-bonding film having, on a base material, a dicing film having a pressure-sensitive adhesive layer and a die-bonding film provided on the pressure-sensitive adhesive layer, the dicing die-bonding film having the following features: (1) the film can express good retention for a semiconductor wafer upon its dicing, and good releasability with which semiconductor chips after the dicing can be released from the base material together with the die-bonding film in a balanced manner irrespective of the sizes and thicknesses of the semiconductor wafer and the semiconductor chips, (2) the film has a small influence on an environment or a human body, and (3) the film can be easily handled.

### BRIEF DESCRIPTION OF THE DRAWINGS

In the accompanying drawings:

FIG. 1 is a schematic sectional view of a dicing die-bonding film according to a preferred embodiment of the present invention;

FIG. 2 is a schematic sectional view of a dicing die-bonding film according to another preferred embodiment of the present invention;

FIG. 3 is a schematic sectional view of a dicing die-bonding film according to still another preferred embodiment of the present invention;

FIG. 4 are schematic process charts showing a method of producing a semiconductor apparatus with a dicing die-bonding film according to a preferred embodiment of the present invention; and

FIG. 5 are schematic process charts showing a method of producing a semiconductor apparatus with a dicing die-bonding film according to another preferred embodiment of the present invention.

### DETAILED DESCRIPTION OF THE PREFERRED EMBODIMENTS

When the present invention is described with reference to a drawing, a portion unnecessary for the description may be omitted in the drawing. In addition, when the present invention is described with reference to a drawing, part or the entirety of the drawing may be enlarged or reduced in size for ease of the description.

<<A. Active Energy Ray-Curable Pressure-Sensitive Adhesive for Re-Release>>

An active energy ray-curable pressure-sensitive adhesive for re-release of the present invention contains an active energy ray-curable polymer (P).

The term “active energy ray” refers to, for example, radioactive rays such as an α-ray, a β-ray, a γ-ray, an electron ray, a neutron ray, and an X-ray, and UV light.

The polymer (P) can be cured by being irradiated with an active energy ray. The curing of the polymer (P) through the irradiation with the active energy ray can increase its degree of cross-linking to reduce the pressure-sensitive adhesive strength of the polymer (P).

The polymer (P) is a polymer obtained by causing a carboxyl group-containing polymer (P3) and an oxazoline group-containing monomer (m3) to react with each other, or a polymer obtained by causing an oxazoline group-containing polymer (P4) and a carboxyl group-containing monomer (m2) to react with each other.

Any appropriate polymer can be adopted as the carboxyl group-containing polymer (P3) as long as the polymer has a carboxyl group. The carboxyl group-containing polymer (P3) is preferably a polymer (P1) constructed of monomer components containing an acrylic acid ester (m1) as a main monomer and the carboxyl group-containing monomer (m2).

Any appropriate polymer can be adopted as the oxazoline group-containing polymer (P4) as long as the polymer has an oxazoline group. The oxazoline group-containing polymer (P4) is preferably a polymer (P2) constructed of monomer components containing the acrylic acid ester (m1) as a main monomer and the oxazoline group-containing monomer (m3).

In one preferred mode (Mode 1) of the polymer (P), the polymer is obtained by causing the polymer (P1) constructed of the monomer components containing the acrylic acid ester (m1) as a main monomer and the carboxyl group-containing monomer (m2), and the oxazoline group-containing monomer (m3) to react with each other.

In one preferred mode (Mode 2) of the polymer (P), the polymer is obtained by causing the polymer (P2) constructed of the monomer components containing the acrylic acid ester (m1) as a main monomer and the oxazoline group-containing monomer (m3), and the carboxyl group-containing monomer (m2) to react with each other.

The carboxyl group-containing monomer (m2) has a carboxyl group and a radical reactive carbon-carbon double bond. The oxazoline group-containing monomer (m3) has an oxazoline group and a radical reactive carbon-carbon double bond.

A lower limit for the glass transition temperature of the polymer (P) is preferably −70° C. or more, more preferably −65° C. or more, still more preferably −60° C. or more, particularly preferably −55° C. or more. An upper limit for the glass transition temperature is preferably −10° C. or less, more preferably −20° C. or less, still more preferably −30° C. or less, particularly preferably −40° C. or less.

When the glass transition temperature of the polymer (P) exceeds −10° C., in, for example, the case where a dicing die-bonding film is obtained by using the active energy ray-curable pressure-sensitive adhesive for re-release of the present invention in the pressure-sensitive adhesive layer of a dicing film, adhesion between the pressure-sensitive adhesive layer and a die-bonding film reduces, and hence the so-called “chip fly” may occur upon dicing.

The polymer (P) preferably contains a low-molecular weight substance at a small content in terms of, for example, the prevention of the contamination of a clean adherend. Accordingly, a lower limit for the weight average molecular weight of the polymer (P) is preferably 350,000 or more, more preferably 450,000 or more, and an upper limit for the weight average molecular weight is preferably 1,000,000 or less, more preferably 800,000 or less.

Examples of the acrylic acid ester (m1) include alkyl acrylates (including linear or branched alkyl acrylates whose alkyl groups each have preferably 1 to 30, more preferably 4 to 18 carbon atoms, such as methyl acrylate, ethyl acrylate, propyl acrylate, isopropyl acrylate, butyl acrylate, isobutyl acrylate, sec-butyl acrylate, t-butyl acrylate, pentyl acrylate, isopentyl acrylate, hexyl acrylate, heptyl acrylate, octyl acrylate, 2-ethylhexyl acrylate, isooctylacrylate, nonylacrylate, decylacrylate, isodecylacrylate, undecyl acrylate, dodecyl acrylate, tridecyl acrylate, tetradecyl acrylate, hexadecyl acrylate, octadecyl acrylate, and eicosyl acrylate), and cycloalkyl acrylates (such as cyclopentyl acrylate and cyclohexyl acrylate).

The acrylic acid esters (m1) may be used alone or in combination.

The acrylic acid ester (m1) is preferably, for example, an acrylic acid ester represented by CH₂═CHCOOR (R represents an alkyl group or a cycloalkyl group, a lower limit for the number of carbon atoms of R is preferably 6 or more, more preferably 8 or more, an upper limit for the number of carbon atoms is preferably 10 or less, more preferably 9 or less, and the number of carbon atoms of R is preferably, for example, 6 to 10).

When the number of carbon atoms of R is less than 6, in, for example, the case where a dicing die-bonding film is obtained by using the active energy ray-curable pressure-sensitive adhesive for re-release of the present invention in the pressure-sensitive adhesive layer of a dicing film, a release strength between the pressure-sensitive adhesive layer and a die-bonding film becomes so large that the pickup property may reduce.

When the number of carbon atoms of R exceeds 10, in, for example, the case where a dicing die-bonding film is obtained by using the active energy ray-curable pressure-sensitive adhesive for re-release of the present invention in the pressure-sensitive adhesive layer of a dicing film, adhesion between the pressure-sensitive adhesive layer and a die-bonding film reduces, and hence the so-called “chip fly” may occur upon dicing.

Particularly preferred examples of the acrylic acid ester (m1) in the present invention include 2-ethylhexyl acrylate and isooctyl acrylate.

Any appropriate content can be adopted as the content of the acrylic acid ester (m1) in the monomer components that construct the polymer (P1) to such an extent that an effect of the present invention is not impaired. A lower limit for the content of the acrylic acid ester (m1) in the monomer components that construct the polymer (P1) is preferably 40 wt % or more, more preferably 50 wt % or more, still more preferably 60 wt % or more, particularly preferably 65 wt % or more, and an upper limit for the content is preferably 97 wt % or less, more preferably 95 wt % or less, still more preferably 93 wt % or less, particularly preferably 91 wt % or less.

When the content of the acrylic acid ester (m1) in the monomer components that construct the polymer (P1) is less than 40 wt %, in, for example, the case where a dicing die-bonding film is obtained by using the active energy ray-curable pressure-sensitive adhesive for re-release of the present invention in the pressure-sensitive adhesive layer of a dicing film, a release strength between the pressure-sensitive adhesive layer and a die-bonding film becomes so large that the pickup property may reduce.

When the content of the acrylic acid ester (m1) in the monomer components that construct the polymer (P1) exceeds 97 wt %, the curability of the polymer (P) by irradiation with an active energy ray reduces. As a result, in, for example, the case where a dicing die-bonding film is obtained by using the active energy ray-curable pressure-sensitive adhesive for re-release of the present invention in the pressure-sensitive adhesive layer of a dicing film, the pickup property may reduce.

Any appropriate content can be adopted as the content of the acrylic acid ester (m1) in the monomer components that construct the polymer (P2) to such an extent that an effect of the present invention is not impaired. A lower limit for the content of the acrylic acid ester (m1) in the monomer components that construct the polymer (P2) is preferably 40 wt % or more, more preferably 50 wt % or more, still more preferably 60 wt % or more, particularly preferably 65 wt % or more, and an upper limit for the content is preferably 97 wt % or less, more preferably 95 wt % or less, still more preferably 93 wt % or less, particularly preferably 91 wt % or less.

When the content of the acrylic acid ester (m1) in the monomer components that construct the polymer (P2) is less than 40 wt %, in, for example, the case where a dicing die-bonding film is obtained by using the active energy ray-curable pressure-sensitive adhesive for re-release of the present invention in the pressure-sensitive adhesive layer of a dicing film, a release strength between the pressure-sensitive adhesive layer and a die-bonding film becomes so large that the pickup property may reduce.

When the content of the acrylic acid ester (m1) in the monomer components that construct the polymer (P2) exceeds 97 wt %, the curability of the polymer (P) by irradiation with an active energy ray reduces. As a result, in, for example, the case where a dicing die-bonding film is obtained by using the active energy ray-curable pressure-sensitive adhesive for re-release of the present invention in the pressure-sensitive adhesive layer of a dicing film, the pickup property may reduce.

Examples of the carboxyl group-containing monomer (m2) include (meth)acrylic acid, carboxyethyl (meth)acrylate, carboxypentyl (meth)acrylate, itaconic acid, maleic acid, fumaric acid, and crotonic acid. The carboxyl group-containing monomer is particularly preferably at least one kind selected from the group consisting of (meth)acrylic acid and carboxyalkyl (meth)acrylates.

The carboxyl group-containing monomers (m2) may be used alone or in combination.

Examples of the oxazoline group-containing monomer (m3) include 2-vinyl-2-oxazoline, 4-methyl-2-vinyl-2-oxazoline, 5-methyl-2-vinyl-2-oxazoline, 2-vinyl-4,4-dimethyl-2-oxazoline, 2-isopropenyl-2-oxazoline, 4-methyl-2-isopropenyl-2-oxazoline, 5-methyl-2-isopropenyl-2-oxazoline, and 2-isopropenyl-4,4-dimethyl-2-oxazoline.

The oxazoline group-containing monomers (m3) may be used alone or in combination.

Any appropriate content can be adopted as the content of the carboxyl group-containing monomer (m2) in the monomer components that construct the polymer (P1) to such an extent that an effect of the present invention is not impaired. A lower limit for the content of the carboxyl group-containing monomer (m2) in the monomer components that construct the polymer (P1) is preferably 3 wt % or more, more preferably 5 wt % or more, still more preferably 7 wt % or more, particularly preferably 9 wt % or more, and an upper limit for the content is preferably 20 wt % or less, more preferably 18 wt % or less, still more preferably 16 wt % or less, particularly preferably 15 wt % or less.

When the content of the carboxyl group-containing monomer (m2) in the monomer components that construct the polymer (P1) is less than 3 wt %, the curability of the polymer (P) by irradiation with an active energy ray reduces. As a result, in, for example, the case where a dicing die-bonding film is obtained by using the active energy ray-curable pressure-sensitive adhesive for re-release of the present invention in the pressure-sensitive adhesive layer of a dicing film, the pickup property may reduce.

When the content of the carboxyl group-containing monomer (m2) in the monomer components that construct the polymer (P1) exceeds wt %, the amount of carboxyl groups remaining in a pressure-sensitive adhesive layer increases. As a result, in, for example, the case where a dicing die-bonding film is obtained by using the active energy ray-curable pressure-sensitive adhesive for re-release of the present invention in the pressure-sensitive adhesive layer of a dicing film, the following trouble may arise. The releasability reduces owing to an increase in an interaction between the pressure-sensitive adhesive layer and a die-bonding film, and hence the pickup property thereof reduces.

Any appropriate content can be adopted as the content of the oxazoline group-containing monomer (m3) in the monomer components that construct the polymer (P2) to such an extent that an effect of the present invention is not impaired. A lower limit for the content of the oxazoline group-containing monomer (m3) in the monomer components that construct the polymer (P2) is preferably 3 wt % or more, more preferably 5 wt % or more, still more preferably 7 wt % or more, particularly preferably 9 wt % or more, and an upper limit for the content is preferably 20 wt % or less, more preferably 18 wt % or less, still more preferably 16 wt % or less, particularly preferably 15 wt % or less.

When the content of the oxazoline group-containing monomer (m3) in the monomer components that construct the polymer (P2) is less than 3 wt %, the curability of the polymer (P) by irradiation with an active energy ray reduces. As a result, in, for example, the case where a dicing die-bonding film is obtained by using the active energy ray-curable pressure-sensitive adhesive for re-release of the present invention in the pressure-sensitive adhesive layer of a dicing film, the pickup property may reduce.

When the content of the oxazoline group-containing monomer (m3) in the monomer components that construct the polymer (P2) exceeds 20 wt %, the amount of oxazoline groups remaining in a pressure-sensitive adhesive layer increases. As a result, in, for example, the case where a dicing die-bonding film is obtained by using the active energy ray-curable pressure-sensitive adhesive for re-release of the present invention in the pressure-sensitive adhesive layer of a dicing film, the following trouble may arise. The releasability reduces owing to an increase in an interaction between the pressure-sensitive adhesive layer and a die-bonding film, and hence the pickup property thereof reduces.

The monomer components that construct the polymer (P1) may contain any other monomer copolymerizable with the above-mentioned acrylic acid ester (m1) as required for the purpose of improving the cohesive strength, heat resistance, or the like of the polymer.

The monomer components that construct the polymer (P2) may contain any other monomer copolymerizable with the above-mentioned acrylic acid ester (m1) as required for the purpose of improving the cohesive strength, heat resistance, or the like of the polymer.

Examples of the other monomer include: hydroxyl group-containing monomers such as 2-hydroxyethyl (meth)acrylate, 2-hydroxypropyl (meth)acrylate, 4-hydroxybutyl (meth)acrylate, 6-hydroxyhexyl (meth)acrylate, 8-hydroxyoctyl (meth)acrylate, 10-hydroxydecyl (meth)acrylate, 12-hydroxylauryl (meth)acrylate, and (4-hydroxymethylcyclohexyl)methyl (meth)acrylate; acid anhydride monomers such as maleic anhydride and itaconic anhydride; sulfonic acid group-containing monomers such as styrenesulfonic acid, allylsulfonic acid, 2-(meth)acrylamide-2-methylpropanesulfonic acid, (meth)acrylamidepropanesulfonic acid, sulfopropyl (meth)acrylate, and (meth)acryloyloxynaphthalenesulfonic acid; phosphoric acid group-containing monomers such as 2-hydroxyethylacryloyl phosphate; acrylamide; and acrylonitrile.

The other monomers may be used alone or in combination.

Any appropriate content can be adopted as the content of the other monomer in the monomer components that construct the polymer (P1) to such an extent that the effect of the present invention is not impaired. A lower limit for the content of the other monomer in the monomer components that construct the polymer (P1) is preferably 0 wt % or more, and an upper limit for the content is preferably 40 wt % or less, more preferably 35 wt % or less, still more preferably 30 wt % or less.

When the content of the other monomer in the monomer components that construct the polymer (P1) exceeds 40 wt %, in, for example, the case where a dicing die-bonding film is obtained by using the active energy ray-curable pressure-sensitive adhesive for re-release of the present invention in the pressure-sensitive adhesive layer of a dicing film, a release strength between the pressure-sensitive adhesive layer and a die-bonding film becomes so large that the pickup property may reduce, or the curability of the polymer (P) by irradiation with an active energy ray reduces, and hence the pickup property may reduce.

Any appropriate content can be adopted as the content of the other monomer in the monomer components that construct the polymer (P2) to such an extent that the effect of the present invention is not impaired. A lower limit for the content of the other monomer in the monomer components that construct the polymer (P2) is preferably 0 wt % or more, and an upper limit for the content is preferably 40 wt % or less, more preferably 35 wt % or less, still more preferably 30 wt % or less.

When the content of the other monomer in the monomer components that construct the polymer (P2) exceeds 40 wt %, in, for example, the case where a dicing die-bonding film is obtained by using the active energy ray-curable pressure-sensitive adhesive for re-release of the present invention in the pressure-sensitive adhesive layer of a dicing film, a release strength between the pressure-sensitive adhesive layer and a die-bonding film becomes so large that the pickup property may reduce, or the curability of the polymer (P) by irradiation with an active energy ray reduces, and hence the pickup property may reduce.

The polymer (P1) is preferably obtained by polymerizing the monomer components containing the acrylic acid ester (m1) as amain monomer and the carboxyl group-containing monomer (m2).

The polymer (P2) is preferably obtained by polymerizing the monomer components containing the acrylic acid ester (m1) as amain monomer and the oxazoline group-containing monomer (m3).

Any appropriate method can be adopted as a method for the polymerization. Examples of the method for the polymerization include solution polymerization, emulsion polymerization, bulk polymerization, and suspension polymerization.

When the polymer (P) is obtained by causing the polymer (P1) constructed of the monomer components containing the acrylic acid ester (m1) as a main monomer and the carboxyl group-containing monomer (m2), and the oxazoline group-containing monomer (m3) to react with each other (Mode 1), a lower limit for the usage of the oxazoline group-containing monomer (m3) with respect to the carboxyl group-containing monomer (m2) in the monomer components that construct the polymer (P1) is preferably 80 mol % or more, more preferably 85 mol % or more, still more preferably 90 mol % or more, and an upper limit for the usage is preferably 150 mol % or less, more preferably 100 mol % or less, still more preferably 98 mol % or less. When the usage of the oxazoline group-containing monomer (m3) is less than 80 mol % with respect to the carboxyl group-containing monomer (m2) in the monomer components that construct the polymer (P1), the amount of carboxyl groups remaining in a pressure-sensitive adhesive layer increases. As a result, in, for example, the case where a dicing die-bonding film is obtained by using the active energy ray-curable pressure-sensitive adhesive for re-release of the present invention in the pressure-sensitive adhesive layer of a dicing film, the following trouble may arise. The releasability reduces owing to an increase in an interaction between the pressure-sensitive adhesive layer and a die-bonding film, and hence the pickup property thereof reduces. When the usage of the oxazoline group-containing monomer (m3) exceeds 150 mol % with respect to the carboxyl group-containing monomer (m2) in the monomer components that construct the polymer (P1), the amount of the oxazoline group-containing monomer (m3) remaining in a pressure-sensitive adhesive layer and the amount of a low-molecular weight substance derived from the monomer increase. As a result, in, for example, the case where a dicing die-bonding film is obtained by using the active energy ray-curable pressure-sensitive adhesive for re-release of the present invention in the pressure-sensitive adhesive layer of a dicing film, a release strength between the pressure-sensitive adhesive layer and a die-bonding film becomes so large that the pickup property may reduce, or an influence on an environment or a human body may enlarge owing to the volatilization of the remaining oxazoline group-containing monomer (m3).

When the polymer (P) is obtained by causing the polymer (P1) constructed of the monomer components containing the acrylic acid ester (m1) as a main monomer and the carboxyl group-containing monomer (m2), and the oxazoline group-containing monomer (m3) to react with each other (Mode 1), any appropriate reaction method can be adopted as a method involving causing the polymer (P1) and the oxazoline group-containing monomer (m3) to react with each other to provide the polymer (P). For example, the following method is given. The oxazoline group-containing monomer (m3) is added to the polymer (P1), and then the mixture is subjected to an addition reaction under any appropriate reaction conditions (e.g., in air at a reaction temperature in the range of 20 to 70° C. for a reaction time of 10 to 100 hours).

When the polymer (P) is obtained by causing the polymer (P2) constructed of the monomer components containing the acrylic acid ester (m1) as a main monomer and the oxazoline group-containing monomer (m3), and the carboxyl group-containing monomer (m2) to react with each other (Mode 2), a lower limit for the usage of the carboxyl group-containing monomer (m2) with respect to the oxazoline group-containing monomer (m3) in the monomer components that construct the polymer (P2) is preferably 80 mol % or more, more preferably 85 mol % or more, still more preferably 90 mol % or more, and an upper limit for the usage is preferably 150 mol % or less, more preferably 100 mol % or less, still more preferably 98 mol % or less. When the usage of the carboxyl group-containing monomer (m2) is less than 80 mol % with respect to the oxazoline group-containing monomer (m3) in the monomer components that construct the polymer (P2), the amount of oxazoline groups remaining in a pressure-sensitive adhesive layer increases. As a result, in, for example, the case where a dicing die-bonding film is obtained by using the active energy ray-curable pressure-sensitive adhesive for re-release of the present invention in the pressure-sensitive adhesive layer of a dicing film, the following trouble may arise. The releasability reduces owing to an increase in an interaction between the pressure-sensitive adhesive layer and a die-bonding film, and hence the pickup property thereof reduces. When the usage of the carboxyl group-containing monomer (m2) exceeds 150 mol % with respect to the oxazoline group-containing monomer (m3) in the monomer components that construct the polymer (P2), the amount of the carboxyl group-containing monomer (m2) remaining in a pressure-sensitive adhesive layer and the amount of a low-molecular weight substance derived from the monomer increase. As a result, in, for example, the case where a dicing die-bonding film is obtained by using the active energy ray-curable pressure-sensitive adhesive for re-release of the present invention in the pressure-sensitive adhesive layer of a dicing film, a release strength between the pressure-sensitive adhesive layer and a die-bonding film becomes so large that the pickup property may reduce, or an influence on an environment or a human body may enlarge owing to the volatilization of the remaining carboxyl group-containing monomer (m2).

When the polymer (P) is obtained by causing the polymer (P2) constructed of the monomer components containing the acrylic acid ester (m1) as a main monomer and the oxazoline group-containing monomer (m3), and the carboxyl group-containing monomer (m2) to react with each other (Mode 2), any appropriate reaction method can be adopted as a method involving causing the polymer (P2) and the carboxyl group-containing monomer (m2) to react with each other to provide the polymer (P). For example, the following method is given. The carboxyl group-containing monomer (m2) is added to the polymer (P2), and then the mixture is subjected to an addition reaction under any appropriate reaction conditions (e.g., in air at a reaction temperature in the range of 20 to 70° C. for a reaction time of 10 to 100 hours).

The cured product of the polymer (P) can be obtained by subjecting the polymer (P) to a cross-linking reaction through irradiation with an active energy ray.

The polymer (P) can be turned into a cured product by being subjected to a cross-linking reaction through irradiation with an active energy ray.

Any appropriate cross-linking agent and any appropriate photopolymerization initiator are preferably used for the polymer (P) in order that the polymer (P) may be subjected to a cross-linking reaction through irradiation with an active energy ray.

Examples of the cross-linking agent include a polyisocyanate compound, an epoxy compound, an aziridine compound, and a melamine-based cross-linking agent.

The cross-linking agents may be used alone or in combination.

Any appropriate amount can be adopted as the usage of the cross-linking agent depending on, for example, the kind of the polymer (P). For example, a lower limit for the usage of the cross-linking agent with respect to the polymer (P) is preferably 0.01 wt % or more, more preferably 0.1 wt % or more, and an upper limit for the usage is preferably 20 wt % or less, more preferably 10 wt % or less.

Examples of the photopolymerization initiator include: α-ketol-based compounds such as 4-(2-hydroxyethoxy)phenyl (2-hydroxy-2-propyl)ketone, α-hydroxy-α,α′-dimethylacetophenone, 2-methyl-2-hydroxypropiophenone, and 1-hydroxycyclohexyl phenyl ketone; acetophenone-based compounds such as methoxyacetophenone, 2,2-dimethoxy-2-phenylacetophenone, 2,2-diethoxyacetophenone, and 2-methyl-1-[4-(methylthio)-phenyl]-2-morpholinopropan-1-one; benzoin ether-based compounds such as benzoin ethyl ether, benzoin isopropyl ether, and anisoin methyl ether; ketal-based compounds such as benzyl dimethyl ketal; aromatic sulfonyl chloride-based compounds such as 2-naphthalenesulfonyl chloride; photoactive oxime-based compounds such as 1-phenone-1,1-propanedione-2-(o-ethoxycarbonyl)oxime; benzophenone-based compounds such as benzophenone, benzoylbenzoic acid, and 3,3′-dimethyl-4-methoxybenzophenone; thioxanthone-based compounds such as thioxanthone, 2-chlorothioxanthone, 2-methylthioxanthone, 2,4-dimethylthioxanthone, isopropylthioxanthone, 2,4-dichlorothioxanthone, 2,4-diethylthioxanthone, and 2,4-diisopropylthioxanthone; camphorquinone; halogenated ketones; acyl phosphine oxides; and acyl phosphonates.

The photopolymerization initiators may be use alone or in combination.

Any appropriate amount can be adopted as the usage of the photopolymerization initiator depending on, for example, the kind of the polymer (P). For example, a lower limit for the usage of the photopolymerization initiator with respect to the polymer (P) is preferably 0.01 wt % or more, more preferably 0.05 wt % or more, and an upper limit for the usage is preferably 20 wt % or less, more preferably 10 wt % or less.

The pressure-sensitive adhesive may contain any other component to such an extent that the effect of the present invention is not impaired.

Examples of the other component include: an uncured polymer (P); a compound that reacts with a carboxyl group; a compound that reacts with an oxazoline group; an active energy ray-curable monomer; an active energy ray-curable oligomer; and additives such as a tackifier and a antioxidant.

The compound that reacts with a carboxyl group can be used for the purpose of, for example, adjusting the amount of remaining carboxyl groups present in the pressure-sensitive adhesive. The compound that reacts with a carboxyl group can be used in any appropriate amount to such an extent that the effect of the present invention is not impaired.

Examples of the compound that reacts with a carboxyl group include an amino group-containing compound, an epoxy group-containing compound, an isocyanate group-containing compound, and a carbodiimide group-containing compound.

The compounds that react with a carboxyl group may be used alone or in combination.

The compound that reacts with an oxazoline group can be used for the purpose of, for example, adjusting the amount of remaining oxazoline groups present in the pressure-sensitive adhesive. The compound that reacts with an oxazoline group can be used in any appropriate amount to such an extent that the effect of the present invention is not impaired.

Examples of the compound that reacts with an oxazoline group include a carboxyl group-containing compound, an aromatic thiol group-containing compound, and a phenol group-containing compound.

The compounds that react with an oxazoline group may be used alone or in combination.

The active energy ray-curable monomer or the active energy ray-curable oligomer can be used for the purpose of, for example, adjusting the pressure-sensitive adhesive strength of the polymer before irradiation with an active energy ray or the pressure-sensitive adhesive strength thereof after the irradiation with the active energy ray.

Examples of the active energy ray-curable monomer include urethane (meth)acrylate, trimethylolpropane tri(meth)acrylate, tetramethylolmethane tetra(meth)acrylate, pentaerythritol tri(meth)acrylate, pentaerythritol tetra(meth)acrylate, dipentaerythritol monohydroxypenta(meth)acrylate, dipentaerythritol hexa(meth)acrylate, and 1,4-butanediol di(meth)acrylate.

The active energy ray-curable monomers may be used alone or in combination.

Examples of the active energy ray-curable oligomer include a urethane-based oligomer, a polyether-based oligomer, a polyester-based oligomer, a polycarbonate-based oligomer, and a polybutadiene-based oligomer.

The active energy ray-curable oligomers may be used alone or in combination.

The active energy ray-curable oligomer preferably has a molecular weight of 100 to 30,000.

The active energy ray-curable monomer and the active energy ray-curable oligomer can be used in any appropriate amount to such an extent that the effect of the present invention is not impaired. For example, a lower limit for the total usage of the active energy ray-curable monomer and the active energy ray-curable oligomer with respect to the polymer (P) is preferably 5 wt % or more, more preferably 40 wt % or more, and an upper limit for the total usage is preferably 500 wt % or less, more preferably 150 wt % or less.

The pressure-sensitive adhesive preferably has an acid value of 10 or less. When the acid value of the pressure-sensitive adhesive exceeds 10, the amount of carboxyl groups remaining in the pressure-sensitive adhesive increases. As a result, in, for example, the case where a dicing die-bonding film is obtained by using the active energy ray-curable pressure-sensitive adhesive for re-release of the present invention in the pressure-sensitive adhesive layer of a dicing film, the following trouble may arise. The releasability reduces owing to an increase in an interaction between the pressure-sensitive adhesive layer and a die-bonding film, and hence the pickup property thereof reduces.

The acid value of the pressure-sensitive adhesive can be adjusted by, for example, adjusting the usages of various compounds such as an oxazoline group-containing compound (B) that can be used in the formation of the pressure-sensitive adhesive.

An evaluation for the acid value can be performed in conformity with JIS K 0070-1992 (potentiometric titration).

The carboxyl group-containing polymer (P3) may be a water dispersion. In this case, the pressure-sensitive adhesive can be an aqueous, active energy ray-curable pressure-sensitive adhesive for re-release.

The oxazoline group-containing polymer (P4) may be a water dispersion. In this case, the pressure-sensitive adhesive can be an aqueous, active energy ray-curable pressure-sensitive adhesive for re-release.

The water dispersion of the carboxyl group-containing polymer (P3) is preferably obtained by polymerizing the monomer components containing the acrylic acid ester (m1) as a main monomer and the carboxyl group-containing monomer (m2).

The water dispersion of the oxazoline group-containing polymer (P4) is preferably obtained by polymerizing the monomer components containing the acrylic acid ester (m1) as a main monomer and the oxazoline group-containing monomer (m3).

An emulsifier, a dispersant, a polymerization initiator, a chain transfer agent, or the like may be further added to the monomer components upon their polymerization.

Any appropriate method can be adopted as a method for the polymerization as long as the water dispersion of the polymer (A) is obtained by the method. Examples of the method for the polymerization include emulsion polymerization and suspension polymerization.

Any appropriate addition method such as bulk addition, continuous addition, or incremental addition can be adopted as a method of adding raw materials in the polymerization.

A polymerization temperature has only to be adjusted in the range of preferably 5° C. to 100° C. depending on, for example, a polymerization initiator to be used.

In the present invention, the above-mentioned polymerization is preferably performed by bulk polymerization because of, for example, its particular effect on a reduction in the amount of organic substance contamination on a wafer. In addition, the polymerization is preferably performed at a low temperature (preferably 50° C. or less, more preferably 30° C. or less). Under those conditions, a high-molecular weight body is easily obtained, the amount of a low-molecular weight component reduces, and the amount of the organic substance contamination on the wafer can be reduced.

An emulsifier is preferably used upon polymerization. An emulsifier from which impurity ions have been removed and which has an SO₄²⁻ ion concentration of 100 μg/g or less is preferably used particularly in, for example, the case where the active energy ray-curable pressure-sensitive adhesive for re-release of the present invention is used in an active energy ray-curable pressure-sensitive adhesive tape or sheet for re-release for processing a semiconductor wafer because the presence of the impurity ions may be of concern. In addition, in the case of an anionic emulsifier, an ammonium salt emulsifier is preferred.

Any appropriate method such as an ion exchange resin method, a film separation method, or a precipitation filtration method for an impurity involving using an alcohol is given as a method of removing the impurity ions.

A reactive emulsifier having a radical polymerizable functional group such as a propenyl group or an allyl ether group is preferred as the emulsifier because the amount of the organic substance contamination on the wafer can be additionally reduced.

Examples of the reactive emulsifier include an “ADEKASOAP SE-10N” manufactured by ADEKA CORPORATION, and an “Aqualon HS-20,” an “Aqualon HS-10,” and an “Aqualon HS-05” manufactured by Dai-ichi Kogyo Seiyaku Co., Ltd.

An emulsifier generally used for, for example, enhancing pressure-sensitive adhesive properties may be used as the emulsifier. Examples of such emulsifier include: anionic emulsifiers such as sodium lauryl sulfate, ammonium lauryl sulfate, sodium dodecylbenzene sulfonate, a sodium polyoxyethylene alkyl ether sulfate, and a sodium polyoxyethylene alkyl phenyl ether sulfate; and nonionic emulsifiers such as a polyoxyethylene alkyl ether and a polyoxyethylene alkyl phenyl ether.

In the present invention, a lower limit for the compounding amount of the emulsifier with respect to 100 parts by weight of all monomer components is preferably 0.1 part by weight or more, more preferably 0.5 part by weight or more, and an upper limit for the compounding amount is preferably 7 parts by weight or less, more preferably 4 parts by weight or less.

When the compounding amount of the emulsifier with respect to 100 parts by weight of all monomer components exceeds 7 parts by weight, the cohesive strength of the pressure-sensitive adhesive reduces, and hence the amount of contamination on an adherend may increase or contamination by the emulsifier itself may occur.

When the compounding amount of the emulsifier with respect to 100 parts by weight of all monomer components is less than 0.1 part by weight, there is a possibility that stable emulsification cannot be maintained.

The emulsifiers may be used alone or in combination.

A dispersant may be used upon polymerization. Examples of the dispersant include: water-soluble synthetic polymers such as polyvinyl alcohol and polymethacrylamide; natural water-soluble polymers such as gelatin, methylcellulose, and starch; and inorganic substances that are hardly water-soluble such as BaSO₄, CaSO₄, BaCO₃, CaCO₃, MgCO₃, Ca₃(PO₄)₂, and Al(OH)₃.

The dispersants may be used alone or in combination.

A polymerization initiator may be used upon polymerization. Examples of the polymerization initiator include: azo-based polymerization initiators such as 2,2′-azobisisobutyronitrile, 2,2′-azobis(2-amidinopropane)dihydrochloride, and 2,2′-azobis(N,N′-dimethyleneisobutylamidine); persulfate-based polymerization initiators such as potassium persulfate and ammonium persulfate; peroxide-based polymerization initiators such as benzoyl peroxide and t-butyl hydroperoxide; and redox-based polymerization initiators such as a combination of aqueous hydrogen peroxide and ascorbic acid, a combination of aqueous hydrogen peroxide and a ferrous salt, and a combination of a persulfate and sodium hydrogen sulfite.

In the present invention, a redox-based polymerization initiator is preferably used because of its particular effect on the reduction in the amount of the organic substance contamination on the wafer. Although the reason for the foregoing is unclear, the foregoing is assumed to originate from the following fact. The use of the redox-based polymerization initiator improves the ease with which a high-molecular weight body is obtained and reduces the amount of a low-molecular weight component. In addition, a redox-based polymerization initiator free of any ionic component is preferably used when the presence of an impurity ion in an active energy ray-curable pressure-sensitive adhesive tape or sheet for re-release for processing a semiconductor wafer is of concern in, for example, the case where the active energy ray-curable pressure-sensitive adhesive for re-release of the present invention is used in the tape or sheet. Such redox-based polymerization initiator is preferably, for example, a combination of aqueous hydrogen peroxide and ascorbic acid. In addition, when the redox-based polymerization initiator is used, the polymerization temperature is preferably 50° C. or less, more preferably 30° C. or less.

In the present invention, any appropriate amount can be adopted as the compounding amount of the polymerization initiator depending on the kind of the initiator and the kinds of the monomer components. The compounding amount of the polymerization initiator with respect to 100 parts by weight of all monomer components preferably falls within the range of 0.001 part by weight to 0.1 part by weight.

The polymerization initiators may be used alone or in combination.

In the present invention, a chain transfer agent may be used for adjusting the molecular weight of each of the carboxyl group-containing polymer (P3) and the oxazoline group-containing polymer (P4). Any appropriate chain transfer agent can be adopted as the chain transfer agent. Examples of the chain transfer agent include lauryl mercaptan, mercaptoacetic acid, 2-mercaptoethanol, 2-ethylhexyl thioglycolate, and 2,3-dimethylcapto-1-propanol.

The chain transfer agents may be used alone or in combination.

### <<B. Active Energy Ray-Curable Pressure-Sensitive Adhesive Tape or Sheet for Re-Release>>

An active energy ray-curable pressure-sensitive adhesive tape or sheet for re-release of the present invention has the active energy ray-curable pressure-sensitive adhesive for re-release of the present invention as a pressure-sensitive adhesive layer on a base material.

Any appropriate thickness can be adopted as the thickness of the pressure-sensitive adhesive layer. For example, a lower limit for the thickness of the pressure-sensitive adhesive layer is preferably 1 μm or more, more preferably 2 μm or more, still more preferably 5 μm or more, and an upper limit for the thickness is preferably 50 μm or less, more preferably 30 μm or less, still more preferably 25 μm or less. As long as the thickness of the pressure-sensitive adhesive layer falls within the above-mentioned range, the tape or sheet can not only prevent the loss of a chip cut surface but also express high pressure-sensitive adhesiveness and high releasability in a balanced manner when used for processing a semiconductor wafer in the production of a semiconductor apparatus.

Antistatic performance can be imparted to the active energy ray-curable pressure-sensitive adhesive tape or sheet for re-release of the present invention. Imparting the antistatic performance to the active energy ray-curable pressure-sensitive adhesive tape or sheet for re-release of the present invention can prevent, for example, the generation of static electricity at the time of, for example, each of the sticking and release of the tape or sheet, and the breakdown of a circuit due to the charging of a workpiece (such as a semiconductor wafer) with the static electricity.

A method of imparting the antistatic performance to the active energy ray-curable pressure-sensitive adhesive tape or sheet for re-release of the present invention is, for example, a method involving adding an antistatic agent or a conductive substance to the base material or the pressure-sensitive adhesive layer, or a method involving providing a conductive layer formed of a charge transfer complex, a metal film, or the like on the base material. Those modes are each preferably, for example, a mode in which an impurity ion that may transform a semiconductor wafer is hardly generated when the tape or sheet is used for processing the semiconductor wafer in the production of a semiconductor apparatus.

Examples of the conductive substance (conductive filler) compounded for the purposes of, for example, imparting conductivity and improving the thermal conductivity, include spherical, needle-shaped, and flaky metal powders made of silver, aluminum, gold, copper, nickel, conductive alloys, and the like, metal oxides such as alumina, amorphous carbon black, and graphite.

The active energy ray-curable pressure-sensitive adhesive tape or sheet for re-release of the present invention may be protected with a separator. The active energy ray-curable pressure-sensitive adhesive tape or sheet for re-release of the present invention can be wound in a roll shape in a state of being protected with the separator. The separator has a function as a protective material for protecting the active energy ray-curable pressure-sensitive adhesive tape or sheet for re-release of the present invention before the tape or sheet is put into practical use. Examples of the separator include a plastic film and paper whose surfaces are coated with releasing agents such as polyethylene terephthalate (PET), polyethylene, polypropylene, a fluorine-based releasing agent, and a long-chain alkyl acrylate-based releasing agent.

In, for example, the case where the active energy ray-curable pressure-sensitive adhesive tape or sheet for re-release of the present invention is not protected with the separator, the tape or sheet may be subjected to a back surface treatment. The back surface treatment can be performed with, for example, a releasing agent such as a silicone-based releasing agent or a long-chain alkyl acrylate-based releasing agent.

### <<B-1. Base Material>>

The base material serves as a strength matrix for the active energy ray-curable pressure-sensitive adhesive tape or sheet for re-release of the present invention.

The base material preferably has active energy ray-transmitting performance. This is because upon, for example, production of a semiconductor apparatus with the active energy ray-curable pressure-sensitive adhesive tape or sheet for re-release of the present invention, the polymer (P) in the pressure-sensitive adhesive layer of the active energy ray-curable pressure-sensitive adhesive tape or sheet for re-release of the present invention is preferably cured by being irradiated with an active energy ray before a semiconductor chip is picked up. It should be noted that the irradiation with the active energy ray in this case has only to be performed at any appropriate timing before the pickup of the semiconductor chip.

Any appropriate thickness can be adopted as the thickness of the base material. The thickness is preferably 5 μm to 200 μm.

Any appropriate material can be adopted as a material for the base material to such an extent that the effect of the present invention can be expressed. Examples of the material for the base material include: polyolefin-based resins such as low density polyethylene, linear low density polyethylene, middle density polyethylene, high density polyethylene, ultralow density polyethylene, ultrahigh molecular polyethylene, random copolymerized polypropylene, block copolymerized polypropylene, homopolypropylene, polybutene, polymethylpentene, an ethylene-vinyl acetate copolymer, an ethylene-(meth)acrylic acid copolymer, an ethylene-(meth)acrylic acid ester (random or alternate) copolymer, an ethylene-butene copolymer, an ethylene-hexene copolymer, and an ionomer resin; styrene-based resins such as polystyrene, an ABS resin, an AS resin, an AAS resin, an ACS resin, an AES resin, an MS resin, an SMA resin, and an MBS resin; chlorine-based resins such as polyvinyl chloride and polyvinylidene chloride; urethane-based resins such as polyurethane; polyester-based resins such as polyethyleneterephthalate and polyethylenenaphthalate; engineering plastics such as polyamide, fully aromatic polyamide (aramid), polycarbonate, polyimide, polyether ether ketone, polyether imide, and polyphenyl sulfide; glass; glass cloth; a fluorocarbon resin; a cellulose-based resin; a silicone resin; a metal (foil); and paper. Further examples of the material for the base material include cross-linked products obtained from the above-mentioned resins and the like.

The base material may be formed only of one kind of a material, or may be formed of two or more kinds of materials. In addition, the base material may be of a single-layer type, or may be of a multilayer type having two or more kinds of layers.

An unstretched base material may be used as the base material, or a base material subjected to a stretching treatment such as uniaxial stretching or biaxial stretching may be used as the base material.

When a base material subjected to a stretching treatment is used, in, for example, the case where the tape or sheet is used for processing a semiconductor wafer in the production of a semiconductor apparatus, a bonding area between the pressure-sensitive adhesive layer and an adherend can be reduced by thermally contracting the base material after dicing, and hence a semiconductor chip can be easily collected.

The surface of the base material may be subjected to any appropriate surface treatment in order that its adhesiveness with an adjacent layer, retaining performance, and the like may be improved. Examples of such surface treatment include: chemical or physical treatments such as a chromic acid treatment, ozone exposure, flame exposure, high-voltage electric exposure, and an ionized radiation treatment; and a coating treatment with an undercoating agent (such as a tacky substance to be described later).

The top of the base material can be provided with a deposited layer of a conductive substance formed of, for example, a metal or an alloy, or an oxide thereof in order that antistatic performance may be imparted to the base material. The thickness of such deposited layer is preferably 30 Å to 500 Å.

### <<C. Method of Producing Active Energy Ray-Curable Pressure-Sensitive Adhesive Tape or Sheet for Re-Release>>

A base material can be formed by any appropriate film formation method. Examples of such film formation method include a calender film formation method, a casting method in an organic solvent, an inflation extrusion method in a closed system, a T-die extrusion method, a co-extrusion method, and a dry laminate method.

Next, a composition containing the pressure-sensitive adhesive of the present invention is applied onto the base material, and is then dried (and cross-linked under heating as required) so that a pressure-sensitive adhesive layer may be formed. A method of applying the composition containing the pressure-sensitive adhesive is, for example, roll coating, screen coating, or gravure coating. The composition may be directly applied onto the base material, or may be applied onto releasing paper or the like whose surface has been subjected to a release treatment before being transferred onto the base material.

### <<D. Dicing Die-Bonding Film>>

A dicing die-bonding film of the present invention is a dicing die-bonding film having, on a base material, a dicing film having a pressure-sensitive adhesive layer and a die-bonding film provided on the pressure-sensitive adhesive layer.

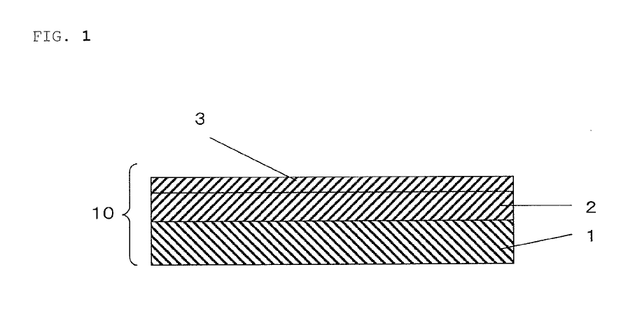

FIG. 1 is a schematic sectional view of an example of a preferred embodiment of the dicing die-bonding film of the present invention.

In FIG. 1, a dicing die-bonding film 10 has, on a base material 1, a dicing film having a pressure-sensitive adhesive layer 2 and a die-bonding film 3 provided on the pressure-sensitive adhesive layer 2. The pressure-sensitive adhesive layer 2 entirely contains the active energy ray-curable pressure-sensitive adhesive for re-release of the present invention or a cured product of the pressure-sensitive adhesive.

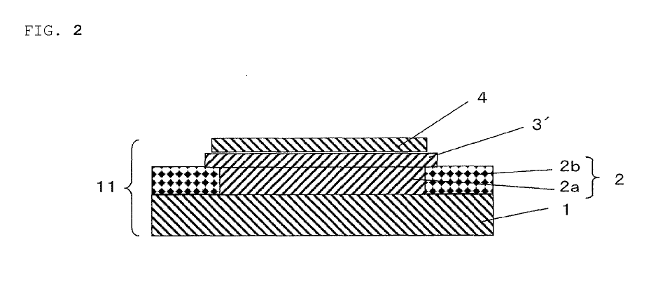

FIG. 2 is a schematic sectional view of an example of another preferred embodiment of the dicing die-bonding film of the present invention.

In FIG. 2, a dicing die-bonding film 11 has, on the base material 1, a dicing film having the pressure-sensitive adhesive layer 2 and a die-bonding film 3′ provided on the pressure-sensitive adhesive layer 2. The die-bonding film 3′ in FIG. 2 is formed on the pressure-sensitive adhesive layer 2 only in a portion to which a semiconductor wafer 4 is attached.

The pressure-sensitive adhesive layer 2 includes: a portion 2a formed of a cured product of the active energy ray-curable pressure-sensitive adhesive for re-release of the present invention as a result of irradiation with an active energy ray; and a portion 2b formed of the active energy ray-curable pressure-sensitive adhesive for re-release of the present invention that has not been irradiated with any active energy ray and hence has not cured.

As described above, the pressure-sensitive adhesive layer 2 in the dicing die-bonding film of the present invention is not needed to entirely contain the cured product of the active energy ray-curable pressure-sensitive adhesive for re-release of the present invention as a result of irradiation with an active energy ray, and may partially contain the cured product of the active energy ray-curable pressure-sensitive adhesive for re-release of the present invention as a result of irradiation with an active energy ray.

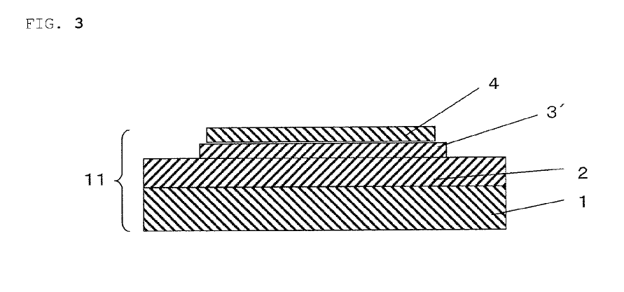

FIG. 3 is a schematic sectional view of an example of still another preferred embodiment of the dicing die-bonding film of the present invention. In FIG. 3, the dicing die-bonding film 11 has, on the base material 1, a dicing film having the pressure-sensitive adhesive layer 2 and the die-bonding film 3′ provided on the pressure-sensitive adhesive layer 2. The die-bonding film 3′ in FIG. 3 is formed on the pressure-sensitive adhesive layer 2 only in a portion to which the semiconductor wafer 4 is attached.

Antistatic performance can be imparted to the dicing die-bonding film of the present invention. Imparting the antistatic performance to the dicing die-bonding film can prevent, for example, the generation of static electricity at the time of, for example, each of the bonding and release of the film, and the breakdown of a circuit due to the charging of a workpiece (such as a semiconductor wafer) with the static electricity.

A method of imparting the antistatic performance to the dicing die-bonding film is, for example, a method involving adding an antistatic agent or a conductive substance to the base material, the pressure-sensitive adhesive layer, or the die-bonding film, or a method involving providing a conductive layer formed of a charge transfer complex, a metal film, or the like on the base material. Those modes are each preferably a mode in which an impurity ion that may transform a semiconductor wafer is hardly generated.

Examples of the conductive substance (conductive filler) compounded for the purposes of, for example, imparting conductivity and improving the thermal conductivity, include spherical, needle-shaped, and flaky metal powders made of silver, aluminum, gold, copper, nickel, conductive alloys, and the like, metal oxides such as alumina, amorphous carbon black, and graphite.

The die-bonding film is preferably non-conductive because an electrical leak can be prevented.

The die-bonding film is preferably protected with a separator. The separator has a function as a protective material for protecting the die-bonding film before the film is put into practical use. In addition, the separator can be used as a supporting base material upon transfer of the die-bonding film onto the pressure-sensitive adhesive layer as well. The separator is released upon attachment of a workpiece onto the die-bonding film of the dicing die-bonding film. Examples of the separator include a plastic film and paper whose surfaces are coated with releasing agents such as polyethylene terephthalate (PET), polyethylene, polypropylene, a fluorine-based releasing agent, and a long-chain alkyl acrylate-based releasing agent.

### <<D-1. Base Material>>

The base material serves as a strength matrix for the dicing die-bonding film.

The base material preferably has active energy ray-transmitting performance. This is because the pressure-sensitive adhesive in the pressure-sensitive adhesive layer of the dicing die-bonding film of the present invention must be previously cured by being irradiated with an active energy ray before a semiconductor chip is picked up. It should be noted that the irradiation with the active energy ray in this case may be performed at any appropriate timing before a semiconductor wafer (workpiece) is fixed on the dicing die-bonding film of the present invention, or may be performed at any appropriate timing during a time period commencing on the fixing of the semiconductor wafer (workpiece) on the dicing die-bonding film of the present invention and ending on the pickup of the semiconductor chip.

The term “active energy ray” refers to, for example, radioactive rays such as an α-ray, a β-ray, a γ-ray, an electron ray, a neutron ray, and an X-ray, and UV light.

Any appropriate thickness can be adopted as the thickness of the base material. The thickness is preferably 5 μm to 200 μm.

Any appropriate material can be adopted as a material for the base material to such an extent that the effect of the present invention can be expressed. Examples of the material for the base material include: polyolefin-based resins such as low density polyethylene, linear low density polyethylene, middle density polyethylene, high density polyethylene, ultralow density polyethylene, ultrahigh molecular polyethylene, random copolymerized polypropylene, block copolymerized polypropylene, homopolypropylene, polybutene, polymethylpentene, an ethylene-vinyl acetate copolymer, an ethylene-(meth)acrylic acid copolymer, an ethylene-(meth)acrylic acid ester (random or alternate) copolymer, an ethylene-butene copolymer, an ethylene-hexene copolymer, and an ionomer resin; styrene-based resins such as polystyrene, an ABS resin, an AS resin, an AAS resin, an ACS resin, an AES resin, an MS resin, an SMA resin, and an MBS resin; chlorine-based resins such as polyvinyl chloride and polyvinylidene chloride; urethane-based resins such as polyurethane; polyester-based resins such as polyethyleneterephthalate and polyethylenenaphthalate; engineering plastics such as polyamide, fully aromatic polyamide (aramid), polycarbonate, polyimide, polyether ether ketone, polyether imide, and polyphenyl sulfide; glass; glass cloth; a fluorocarbon resin; a cellulose-based resin; a silicone resin; a metal (foil); and paper. Further examples of the material for the base material include cross-linked products obtained from the above-mentioned resins and the like.

The base material may be formed only of one kind of a material, or may be formed of two or more kinds of materials. In addition, the base material may be of a single-layer type, or may be of a multilayer type having two or more kinds of layers.

An unstretched base material may be used as the base material, or a base material subjected to a stretching treatment such as uniaxial stretching or biaxial stretching may be used as the base material.

When a base material subjected to a stretching treatment is used, a bonding area between the pressure-sensitive adhesive layer and the die-bonding film can be reduced by thermally contracting the base material after dicing, and hence a semiconductor chip can be easily collected.

The surface of the base material may be subjected to any appropriate surface treatment in order that its adhesiveness with an adjacent layer, retaining performance, and the like may be improved. Examples of such surface treatment include: chemical or physical treatments such as a chromic acid treatment, ozone exposure, flame exposure, high-voltage electric exposure, and an ionized radiation treatment; and a coating treatment with an undercoating agent (such as a tacky substance to be described later).

The top of the base material can be provided with a deposited layer of a conductive substance formed of, for example, a metal or an alloy, or an oxide thereof in order that antistatic performance may be imparted to the base material. The thickness of such deposited layer is preferably 30 Å to 500 Å.

<<D-2. Pressure-Sensitive Adhesive Layer>>

The pressure-sensitive adhesive layer contains the active energy ray-curable pressure-sensitive adhesive for re-release of the present invention or a cured product of the pressure-sensitive adhesive.

When the pressure-sensitive adhesive layer contains the active energy ray-curable pressure-sensitive adhesive for re-release of the present invention, the curing of the active energy ray-curable pressure-sensitive adhesive for re-release of the present invention through irradiation with an active energy ray can increase its degree of cross-linking to reduce the pressure-sensitive adhesive strength of the active energy ray-curable pressure-sensitive adhesive for re-release of the present invention.

When the pressure-sensitive adhesive layer contains the cured product of the active energy ray-curable pressure-sensitive adhesive for re-release of the present invention as a result of irradiation with an active energy ray, the curing of the active energy ray-curable pressure-sensitive adhesive for re-release of the present invention through irradiation with an active energy ray can increase its degree of cross-linking to reduce the pressure-sensitive adhesive strength of the active energy ray-curable pressure-sensitive adhesive for re-release of the present invention. For example, the pressure-sensitive adhesive layer 2 shown in FIG. 2 includes, in the portion to which the semiconductor wafer is attached, the portion 2a formed of a cured product obtained by curing the active energy ray-curable pressure-sensitive adhesive for re-release of the present invention through irradiation with an active energy ray, and the portion 2b formed of the active energy ray-curable pressure-sensitive adhesive for re-release of the present invention that has not been irradiated with any active energy ray and hence has not cured, and there exists a difference in pressure-sensitive adhesive strength between the portion 2a and the portion 2b.

In FIG. 2, the die-bonding film 3′ is attached to the entirety of the portion 2a with its pressure-sensitive adhesive strength reduced by the curing of the active energy ray-curable pressure-sensitive adhesive for re-release of the present invention through irradiation with an active energy ray, and to part of the portion 2b formed of the active energy ray-curable pressure-sensitive adhesive for re-release of the present invention that has not been irradiated with any active energy ray and hence has not cured. In FIG. 2, an interface between the portion 2a of the pressure-sensitive adhesive layer 2 and the die-bonding film 3′ has such nature that the die-bonding film 3′ peels easily at the time of pickup because the pressure-sensitive adhesive strength of the portion 2a has reduced. On the other hand, in FIG. 2, an interface between the portion 2b and the die-bonding film 3′ can secure retention upon dicing because the portion 2b has a pressure-sensitive adhesive strength enough to stick to the die-bonding film 3′.

In the pressure-sensitive adhesive layer 2 shown in FIG. 2, the portion 2b formed of the active energy ray-curable pressure-sensitive adhesive for re-release of the present invention that has not been irradiated with any active energy ray and hence has not cured can fix a dicing ring. For example, a ring made of a metal such as stainless steel or a ring made of a resin can be used as the dicing ring.

When the pressure-sensitive adhesive layer contains the active energy ray-curable pressure-sensitive adhesive for re-release of the present invention, irradiation with an active energy ray has only to be performed at any appropriate timing during a time period commencing on the fixing of a semiconductor wafer (workpiece) on the dicing die-bonding film of the present invention and ending on the pickup of a semiconductor chip.

The pressure-sensitive adhesive layer 2 shown in FIG. 3 can fix a dicing ring. For example, a ring made of a metal such as stainless steel or a ring made of a resin can be used as the dicing ring.

As described above, properly designing the pressure-sensitive adhesive layer enables the dicing die-bonding film of the present invention to support the die-bonding film in a balanced manner in terms of both adhesion and releasability.

Any appropriate method can be adopted as a method of forming the pressure-sensitive adhesive layer. Examples of the method of forming the pressure-sensitive adhesive layer include a method involving forming the pressure-sensitive adhesive layer directly on the base material, and a method involving transferring the pressure-sensitive adhesive layer provided on a separator onto the base material.

When the pressure-sensitive adhesive layer contains the cured product of the active energy ray-curable pressure-sensitive adhesive for re-release of the present invention as a result of irradiation with an active energy ray, the curing of the active energy ray-curable pressure-sensitive adhesive for re-release of the present invention may be performed before the die-bonding film is attached, or may be performed after the die-bonding film has been attached.

With regard to the curing of the active energy ray-curable pressure-sensitive adhesive for re-release of the present invention through irradiation with an active energy ray in the pressure-sensitive adhesive layer, only part of the active energy ray-curable pressure-sensitive adhesive for re-release of the present invention can be cured by being irradiated with the active energy ray as shown in FIG. 2 (the cured portion is the portion 2a, and the uncured portion is the portion 2b).

Any appropriate method can be adopted as a method of partially curing the active energy ray-curable pressure-sensitive adhesive for re-release of the present invention through irradiation with an active energy ray. Examples of the method of partially curing the active energy ray-curable pressure-sensitive adhesive for re-release of the present invention through the irradiation with the active energy ray include a method involving partially applying the active energy ray, and a method involving providing at least one surface of the base material with a material that blocks the active energy ray through printing, vapor deposition, or the like.

The irradiation cumulative light quantity of an active energy ray for curing the active energy ray-curable pressure-sensitive adhesive for re-release of the present invention is preferably 50 to 500 mJ/cm². When the irradiation cumulative light quantity of the active energy ray for curing the polymer (P) is set to fall within the above-mentioned range, adhesion enough to suppress the occurrence of the so-called “chip fly” upon dicing can be retained, and good pickup property can be expressed upon pickup.

When curing inhibition due to oxygen occurs upon irradiation of the active energy ray-curable pressure-sensitive adhesive for re-release of the present invention with the active energy ray, oxygen is preferably blocked off the surface of the pressure-sensitive adhesive layer. A method of blocking oxygen is, for example, a method involving covering the surface of the pressure-sensitive adhesive layer with a separator, or a method involving applying the active energy ray in an atmosphere of an inert gas such as a nitrogen gas.

Any appropriate thickness can be adopted as the thickness of the pressure-sensitive adhesive layer. For example, a lower limit for the thickness of the pressure-sensitive adhesive layer is preferably 1 μm or more, more preferably 2 μm or more, still more preferably 5 μm or more, and an upper limit for the thickness is preferably 50 μm or less, more preferably 30 μm or less, still more preferably 25 μm or less. As long as the thickness of the pressure-sensitive adhesive layer falls within the above-mentioned range, the dicing die-bonding film can not only prevent the loss of a chip cut surface but also support the die-bonding film in a balanced manner in terms of both adhesion and releasability.

### <<D-3. Die-Bonding Film>>

The dicing die-bonding film of the present invention has, on the base material, the dicing film having the pressure-sensitive adhesive layer and the die-bonding film provided on the pressure-sensitive adhesive layer.

The die-bonding film may have a construction formed only of, for example, a single adhesive layer, or may have a multilayer structure having two or more layers obtained by appropriately combining, for example, thermoplastic resins having different glass transition temperatures or thermosetting resins having different thermosetting temperatures.

As cutting water is used in the step of dicing a semiconductor wafer, the die-bonding film may absorb moisture to have a water content equal to or higher than that in its ordinary state. When such die-bonding film having a high water content is bonded to a substrate or the like, water vapor may accumulate at a bonding interface at an after-cure stage to cause a float. Therefore, such a problem that the above-mentioned float occurs can be avoided by constructing an adhesive for bonding a die as described below. A core material having high moisture permeability is interposed between the die adhesives. This is because water vapor diffuses through the film at the after-cure stage.

From the above-mentioned viewpoint, the die-bonding film may have such a multilayer structure that an adhesive layer is formed on one, or each of both, of the surfaces of the core material.

Examples of the above-mentioned core material include films (such as a polyimide film, a polyester film, a polyethyleneterephthalate film, a polyethylenenaphthalate film, and a polycarbonate film), a resin substrate reinforced with glass fiber or plastic-made nonwoven fiber, a silicon substrate, and a glass substrate.

The die-bonding film contains an epoxy resin in its adhesive layer. The epoxy resin has the following advantage. The content of an ionic impurity or the like which corrodes a semiconductor device is small.

A lower limit for the content of the epoxy resin in the adhesive layer of the die-bonding film is preferably 50 wt % or more, more preferably 70 wt % or more, still more preferably 90 wt % or more, particularly preferably 95 wt % or more, and an upper limit for the content is 100 wt % or less.

Any appropriate epoxy resin can be adopted as the epoxy resin as long as the epoxy resin is one generally used in an adhesive composition. Examples of the epoxy resin include: bifunctional epoxy resins and polyfunctional epoxy resins of a bisphenol A type, a bisphenol F type, a bisphenol S type, a brominated bisphenol A type, a hydrogenated bisphenol A type, a bisphenol AF type, a biphenyl type, a naphthalene type, a fluorene type, a phenol novolac type, an ortho-cresol novolac type, a trishydroxyphenylmethane type, a tetraphenylolethane type, and the like; a hydantoin type epoxy resin; a triglycidyl isocyanurate type epoxy resin; and a glycidylamine type epoxy resin.

The epoxy resins may be used alone or in combination

Particularly preferred examples of the epoxy resin include a novolac type epoxy resin, a biphenyl type epoxy resin, a trishydroxyphenylmethane type epoxy resin, and a tetraphenylolethane type epoxy resin. These epoxy resins are each rich in reactivity with a phenol resin as a curing agent, and are each excellent in heat resistance or the like.

The adhesive layer of the die-bonding film may appropriately contain any other thermosetting resin or thermoplastic resin as required. Such resins may be used alone or in combination.

Examples of the thermosetting resin include a phenol resin, an amino resin, an unsaturated polyester resin, a polyurethane resin, a silicone resin, and a thermosetting polyimide resin.

A phenol resin is preferably used as a curing agent for the epoxy resin.

The phenol resin can act as a curing agent for the epoxy resin, and examples of the phenol resin include: novolac type phenol resins such as a phenol novolac resin, a phenol aralkyl resin, a cresol novolac resin, a tert-butyl phenol novolac resin, and a nonyl phenol novolac resin; resol type phenol resins; and polyoxystyrenes such as polyparaoxystyrene.

Particularly preferred examples of the phenol resin include a phenol novolac resin and a phenol aralkyl resin because these phenol resins can each improve the connection reliability of the semiconductor device.

With regard to a compounding ratio between the epoxy resin and the phenol resin, a lower limit for the amount of a hydroxyl group in the phenol resin per 1 equivalent of an epoxy group in the epoxy resin component is preferably 0.5 equivalent or more, more preferably 0.8 equivalent or more, and an upper limit for the amount is preferably 2.0 equivalents or less, more preferably 1.2 equivalents or less. When the compounding ratio between the epoxy resin and the phenol resin deviates from the above-mentioned range, a sufficient curing reaction does not proceed, and hence the characteristics of an epoxy resin-cured product may be apt to deteriorate.

Examples of the thermoplastic resin include a natural rubber, a butyl rubber, an isoprene rubber, a chloroprene rubber, an ethylene-vinyl acetate copolymer, an ethylene-acrylic acid copolymer, an ethylene-acrylic acid ester copolymer, a polybutadiene resin, a polycarbonate resin, a thermoplastic polyimide resin, polyamide resins such as 6-nylon and 6,6-nylon, a phenoxy resin, an acrylic resin, saturated polyester resins such as PET and PBT, a polyamide-imide resin, and a fluorocarbon resin.

An acrylic resin is particularly preferred as the thermoplastic resin because of its small ionic impurity content, high heat resistance, and ability to secure the reliability of a semiconductor device.

Any appropriate acrylic resin can be adopted as the acrylic resin. The acrylic resin is, for example, a polymer obtained by polymerizing monomer components containing one kind or two or more kinds of acrylic or methacrylic acid esters each having the following linear or branched alkyl group. A lower limit for the number of carbon atoms of the group is preferably 4 or more, and an upper limit for the number of carbon atoms is preferably 30 or less, more preferably 18 or less.

Examples of the alkyl group include a methyl group, an ethyl group, a propyl group, an isopropyl group, an n-butyl group, a t-butyl group, an isobutyl group, an amyl group, an isoamyl group, a hexyl group, a heptyl group, a cyclohexyl group, a 2-ethylhexyl group, an octyl group, an isooctyl group, a nonyl group, an isononyl group, a decyl group, an isodecyl group, an undecyl group, a lauryl group, a tridecyl group, a tetradecyl group, a stearyl group, an octadecyl group, and a dodecyl group.

The above-mentioned monomer components that form the acrylic resin may contain any appropriate other monomer.

Examples of the other monomer include: carboxyl group-containing monomers such as acrylic acid, methacrylic acid, carboxyethyl acrylate, carboxypentyl acrylate, itaconic acid, maleic acid, fumaric acid, and crotonic acid; acid anhydride monomers such as maleic anhydride and itaconic anhydride; hydroxyl group-containing monomers such as 2-hydroxyethyl (meth)acrylate, 2-hydroxypropyl (meth)acrylate, 4-hydroxybutyl (meth)acrylate, 6-hydroxyhexyl (meth)acrylate, 8-hydroxyoctyl acrylate, 10-hydroxydecyl (meth)acrylate, 12-hydroxylauryl (meth)acrylate, and (4-hydroxymethylcyclohexyl)-methyl acrylate; sulfonic acid group-containing monomers such as styrenesulfonic acid, allylsulfonic acid, 2-(meth)acrylamide-2-methylpropanesulfonic acid, (meth)acrylamidepropanesulfonic acid, sulfopropyl (meth)acrylate, and (meth)acryloyloxynaphthalenesulfonic acid; phosphoric acid group-containing monomers such as 2-hydroxyethylacryloyl phosphate.

A polyfunctional compound capable of reacting with, for example, a functional group at a molecular chain terminal of a polymer in the adhesive layer of the die-bonding film may be added as a cross-linking agent to the adhesive layer upon its production in order that the layer may be cross-linked to some extent in advance. The addition of such polyfunctional compound can improve the adhesive characteristics of the layer under high temperatures, and can improve the heat resistance thereof. The polyfunctional compounds may be used alone or in combination.

The adhesive layer of the die-bonding film can be appropriately compounded with any appropriate other additive as required. The other additives may be used alone or in combination.

Examples of the other additive include a flame retardant, a silane coupling agent, and an ion trapping agent.

Examples of the flame retardant include antimony trioxide, antimony pentoxide, and a brominated epoxy resin.

Examples of the silane coupling agent include β-(3,4-epoxycyclohexyl)ethyltrimethoxysilane, γ-glycidoxypropyltrimethoxysilane, and γ-glycidoxypropylmethyldiethoxysilane.

Examples of the ion trapping agent include hydrotalcites and bismuth hydroxide.

Any appropriate thickness can be adopted as the thickness of the die-bonding film. A lower limit for the thickness of the die-bonding film is preferably 5 μm or more, and an upper limit for the thickness is preferably 100 μm or less, more preferably 50 μm or less.

### <<E. Method of Producing Dicing Die-Bonding Film>>

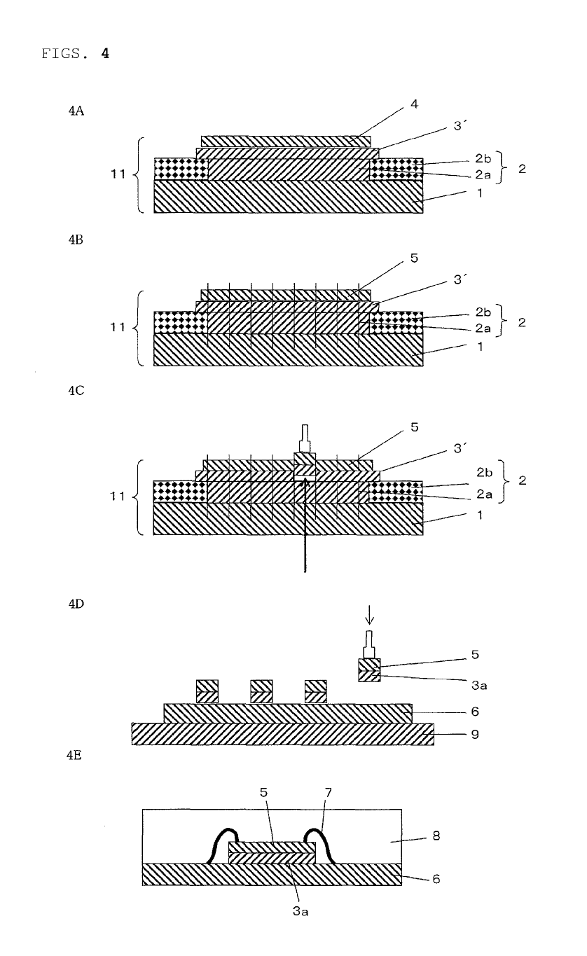

A method of producing the dicing die-bonding film of the present invention in the case where the pressure-sensitive adhesive layer contains a cured product of the active energy ray-curable pressure-sensitive adhesive for re-release of the present invention as a result of irradiation with an active energy ray (Production Mode 1) is described by taking the dicing die-bonding film 11 (FIG. 2 and FIG. 4A) as an example.

The base material 1 can be formed by any appropriate film formation method. Examples of such film formation method include a calender film formation method, a casting method in an organic solvent, an inflation extrusion method in a closed system, a T-die extrusion method, a co-extrusion method, and a dry laminate method.

Next, a composition containing the pressure-sensitive adhesive is applied onto the base material 1, and is then dried (and cross-linked under heating as required) so that the pressure-sensitive adhesive layer may be formed. A mode for applying the composition containing the pressure-sensitive adhesive is, for example, roll coating, screen coating, or gravure coating. The composition may be directly applied onto the base material 1, or may be applied onto releasing paper or the like whose surface has been subjected to a release treatment before being transferred onto the base material 1. After that, only a region somewhat smaller than a portion to which the die-bonding film is attached is irradiated with an active energy ray so that the pressure-sensitive adhesive may be cured. As a result, the pressure-sensitive adhesive layer 2 including the cured portion 2a and the uncured portion 2b is obtained.

Next, a formation material for forming the die-bonding film 3 is applied onto releasing paper so as to have a predetermined thickness. Further, the material is dried under a predetermined condition so that an applied layer may be formed. The applied layer is cut and transferred onto the pressure-sensitive adhesive layer 2 so that the die-bonding film 3 may be formed.

Alternatively, the die-bonding film 3 can be formed by: directly applying the formation material for forming the die-bonding film 3 onto the pressure-sensitive adhesive layer 2; and drying the applied material under a predetermined condition.

Thus, the dicing die-bonding film 11 according to the present invention can be obtained in accordance with Production Mode 1. Although in this example, the irradiation of the pressure-sensitive adhesive with the active energy ray is performed before the die-bonding film is attached, the irradiation may be performed after the die-bonding film has been attached.

A method of producing the dicing die-bonding film of the present invention in the case where the pressure-sensitive adhesive layer contains a cured product of the active energy ray-curable pressure-sensitive adhesive for re-release of the present invention as a result of irradiation with an active energy ray (Production Mode 2) is described by taking the dicing die-bonding film 10 (FIG. 1) as an example.

The base material 1 can be formed by any appropriate film formation method. Examples of such film formation method include a calender film formation method, a casting method in an organic solvent, an inflation extrusion method in a closed system, a T-die extrusion method, a co-extrusion method, and a dry laminate method.

Next, a composition containing the pressure-sensitive adhesive is applied onto the base material 1, and is then dried (and cross-linked under heating as required) so that the pressure-sensitive adhesive layer may be formed. A mode for applying the composition containing the pressure-sensitive adhesive is, for example, roll coating, screen coating, or gravure coating. The composition may be directly applied onto the base material 1, or may be applied onto releasing paper or the like whose surface has been subjected to a release treatment before being transferred onto the base material 1.

Next, a formation material for forming the die-bonding film 3 is applied onto releasing paper so as to have a predetermined thickness. Further, the material is dried under a predetermined condition so that an applied layer may be formed. The applied layer is cut and transferred onto the pressure-sensitive adhesive layer 2 so that the die-bonding film 3 may be formed.

Alternatively, the die-bonding film 3 can be formed by: directly applying the formation material for forming the die-bonding film 3 onto the pressure-sensitive adhesive layer 2; and drying the applied material under a predetermined condition.

Thus, the dicing die-bonding film 10 according to the present invention can be obtained in accordance with Production Mode 2.

### <<F. Method of Producing Semiconductor Apparatus>>

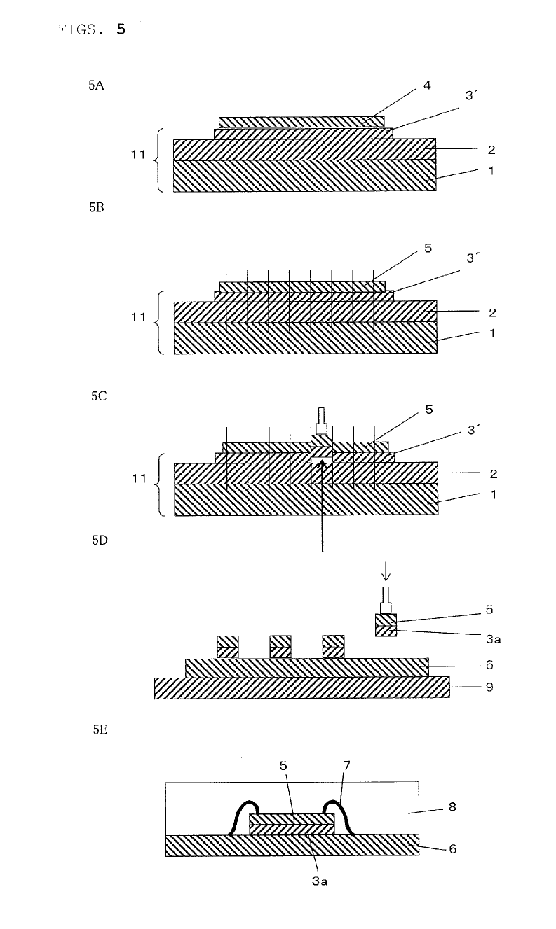

The dicing die-bonding film of the present invention can be used as described below by appropriately releasing a separator appropriately provided on the die-bonding film. Hereinafter, a method of producing a semiconductor apparatus is described by taking the case where the dicing die-bonding film 11 is used as an example with reference to FIG. 4 for the case where the pressure-sensitive adhesive layer contains a cured product of the active energy ray-curable pressure-sensitive adhesive for re-release of the present invention as a result of irradiation with an active energy ray, or to FIG. 5 for the case where the pressure-sensitive adhesive layer contains the active energy ray-curable pressure-sensitive adhesive for re-release of the present invention.

First, the method of producing a semiconductor apparatus is described with reference to FIG. 4 for the case where the pressure-sensitive adhesive layer contains the cured product of the active energy ray-curable pressure-sensitive adhesive for re-release of the present invention as a result of the irradiation with the active energy ray.

First, as shown in FIG. 4A, the semiconductor wafer 4 is crimped onto the die-bonding film 3′ in the dicing die-bonding film 11, and is then fixed by being bonded and retained (mounting step). This step is performed while the wafer is pressed with pressing means such as a crimp roll.

Next, as shown in FIG. 4B, the semiconductor wafer 4 is subjected to dicing (dicing step). The semiconductor wafer 4 is cut into a predetermined size by the dicing so as to turn into individual chips. Thus, semiconductor chips 5 are produced. The dicing is performed from, for example, the circuit surface side of the semiconductor wafer 4 in accordance with an ordinary method. In this step, for example, a cutting mode referred to as “full cut” involving performing cutting to the depth of the dicing die-bonding film 11 can be adopted. Any appropriate apparatus can be used as a dicing apparatus to be used in this step. The semiconductor wafer is bonded and fixed onto the dicing die-bonding film 11. Accordingly, a chip loss and chip fly can be suppressed, and the breakage of the semiconductor wafer 4 can also be suppressed.

Next, as shown in FIG. 4C, the semiconductor chips 5 are picked up in order that the semiconductor chips bonded and fixed onto the dicing die-bonding film 11 may be released (pickup step). Any appropriate method can be adopted as a method for the pickup. The method for the pickup is, for example, a method involving pushing up each of the semiconductor chips 5 from the side of the dicing die-bonding film 11 with a needle and picking up the semiconductor chips 5 thus pushed up with a pickup apparatus.

Next, as shown in FIG. 4D, the semiconductor chips 5 thus picked up are each bonded and fixed onto an adherend 6 through a die-bonding film 3a (die-bonding step). The adherend 6 is mounted on a heat block 9. Examples of the adherend 6 include a lead frame, a TAB film, a substrate, and a separately produced semiconductor chip. For example, the adherend 6 may be such a deformable adherend as to be easily deformed, or may be a non-deformable adherend that is hard to deform (such as a semiconductor wafer). Any appropriate substrate can be adopted as the above-mentioned substrate. Examples of the above-mentioned lead frame include: metal lead frames such as a Cu lead frame and a 42-alloy lead frame; and organic substrates formed of glass epoxy, bismaleimide-triazine (BT), polyimide, and the like. The adherend 6 may be a circuit board which can be used while being electrically connected to a semiconductor device that is mounted thereon. When the die-bonding film 3a is thermosetting, each of the semiconductor chips 5 is bonded and fixed onto the adherend 6 by curing the film under heating so as to have an improved heat-resisting strength. It should be noted that the semiconductor chips 5 each of which is bonded and fixed onto, for example, the substrate through the portion 3a to which the semiconductor wafer is attached can be subjected to a reflow step.

Subsequently, as shown in FIG. 4E, the following wire bonding is performed (bonding step). The tip of a terminal portion (inner lead) of the adherend 6 and an electrode pad (not shown) on each of the semiconductor chips 5 are electrically connected to each other with a bonding wire 7. After the step, the semiconductor chip is sealed with a sealing resin 8, and then the sealing resin 8 is after-cured.

Thus, the semiconductor apparatus is produced for the case where the pressure-sensitive adhesive layer contains the cured product of the active energy ray-curable pressure-sensitive adhesive for re-release of the present invention as a result of the irradiation with the active energy ray.

Next, the method of producing a semiconductor apparatus is described with reference to FIG. 5 for the case where the pressure-sensitive adhesive layer contains the active energy ray-curable pressure-sensitive adhesive for re-release of the present invention.

First, as shown in FIG. 5A, the semiconductor wafer 4 is crimped onto the die-bonding film 3′ in the dicing die-bonding film 11, and is then fixed by being bonded and retained (mounting step). This step is performed while the wafer is pressed with pressing means such as a crimp roll.

Next, as shown in FIG. 5B, the semiconductor wafer 4 is subjected to dicing (dicing step). The semiconductor wafer 4 is cut into a predetermined size by the dicing so as to turn into individual chips. Thus, the semiconductor chips 5 are produced. The dicing is performed from, for example, the circuit surface side of the semiconductor wafer 4 in accordance with an ordinary method. In this step, for example, a cutting mode referred to as “full cut” involving performing cutting to the depth of the dicing die-bonding film 11 can be adopted. Any appropriate apparatus can be used as a dicing apparatus to be used in this step. The semiconductor wafer is bonded and fixed onto the dicing die-bonding film 11. Accordingly, a chip loss and chip fly can be suppressed, and the breakage of the semiconductor wafer 4 can also be suppressed.

Next, as shown in FIG. 5C, the semiconductor chips 5 are picked up in order that the semiconductor chips bonded and fixed onto the dicing die-bonding film 11 may be released (pickup step). Any appropriate method can be adopted as a method for the pickup. The method for the pickup is, for example, a method involving pushing up each of the semiconductor chips 5 from the side of the dicing die-bonding film 11 with a needle and picking up the semiconductor chips 5 thus pushed up with a pickup apparatus.

Here, the pickup is performed after the pressure-sensitive adhesive layer has been irradiated with an active energy ray at any appropriate timing after the mounting step.

With regard to the curing of the active energy ray-curable pressure-sensitive adhesive for re-release of the present invention through irradiation with an active energy ray in the pressure-sensitive adhesive layer, the entirety of the active energy ray-curable pressure-sensitive adhesive for re-release of the present invention may be cured by being irradiated with the active energy ray, or only part of the active energy ray-curable pressure-sensitive adhesive for re-release of the present invention (e.g., only the portion on which the semiconductor wafer 4 is fixed) may be cured by being irradiated with the active energy ray.

Any appropriate method can be adopted as a method of partially curing the active energy ray-curable pressure-sensitive adhesive for re-release of the present invention through the irradiation with the active energy ray. Examples of the method of partially curing the active energy ray-curable pressure-sensitive adhesive for re-release of the present invention through the irradiation with the active energy ray include a method involving partially applying the active energy ray, and a method involving providing at least one surface of the base material with a material that blocks the active energy ray through printing, vapor deposition, or the like.

The irradiation cumulative light quantity of the active energy ray for curing the active energy ray-curable pressure-sensitive adhesive for re-release of the present invention is preferably 50 to 500 mJ/cm². When the irradiation cumulative light quantity of the active energy ray for curing the polymer (P) is set to fall within the above-mentioned range, for example, adhesion enough to suppress the occurrence of the so-called “chip fly” upon dicing can be retained, good pickup property can be expressed upon pickup, and excessive progress of cross-linking can be suppressed so that good releasability may be expressed.

Next, as shown in FIG. 5D, the semiconductor chips 5 thus picked up are each bonded and fixed onto the adherend 6 through the die-bonding film 3a (die-bonding step). The adherend 6 is mounted on the heat block 9. Examples of the adherend 6 include a lead frame, a TAB film, a substrate, and a separately produced semiconductor chip. For example, the adherend 6 may be such a deformable adherend as to be easily deformed, or may be a non-deformable adherend that is hard to deform (such as a semiconductor wafer). Any appropriate substrate can be adopted as the above-mentioned substrate. Examples of the above-mentioned lead frame include: metal lead frames such as a Cu lead frame and a 42-alloy lead frame; and organic substrates formed of glass epoxy, bismaleimide-triazine (BT), polyimide, and the like. The adherend 6 may be a circuit board which can be used while being electrically connected to a semiconductor device that is mounted thereon. When the die-bonding film 3a is thermosetting, each of the semiconductor chips 5 is bonded and fixed onto the adherend 6 by curing the film under heating so as to have an improved heat-resisting strength. It should be noted that the semiconductor chips 5 each of which is bonded and fixed onto, for example, the substrate through the portion 3a to which the semiconductor wafer is attached can be subjected to a reflow step.

Subsequently, as shown in FIG. 5E, the following wire bonding is performed (bonding step). The tip of a terminal portion (inner lead) of the adherend 6 and an electrode pad (not shown) on each of the semiconductor chips 5 are electrically connected to each other with the bonding wire 7. After the step, the semiconductor chip is sealed with the sealing resin 8, and then the sealing resin 8 is after-cured.

Thus, the semiconductor apparatus is produced for the case where the pressure-sensitive adhesive layer contains the active energy ray-curable pressure-sensitive adhesive for re-release of the present invention.

Hereinafter, the present invention is described specifically by way of examples. However, the present invention is by no means limited to these examples. It should be noted that in the examples and the like, test and evaluation methods are as described below, and the term “part(s)” means “part(s) by weight.”

### <Measurement of Glass Transition Temperature>

The loss modulus of a sample having a thickness of about 1.5 mm was measured with a dynamic viscoelasticity-measuring apparatus “ARES” manufactured by Rheometric and a parallel-plate jig having a diameter of 7.9 mm at a frequency of 1 Hz and a rate of temperature increase of 5° C./min, and the temperature at which the resultant loss modulus peaked was defined as a glass transition temperature.

### <Evaluation for Pickup Property (for Examples 1-1 to 1-5, Examples 2-1 to 2-6, Comparative Examples 1-1 and 1-2, and Comparative Examples 2-1 and 2-2)>

Pickup was performed with each of dicing die-bonding films in the respective examples and comparative examples according to the following procedure after the dicing of a semiconductor wafer had been performed. Then, the respective dicing die-bonding films were evaluated for their pickup properties.

The backside of the semiconductor wafer (having a diameter of 8 inches and a thickness of 0.6 mm) was polished (grinding apparatus: “DFG-8560” manufactured by DISCO Corporation), and the resultant mirror wafer having a thickness of 0.075 mm was used as a workpiece.

After a separator had been released from a dicing die-bonding film, the above-mentioned mirror wafer was attached onto the die-bonding film by being crimped with a roll at 40° C. (attaching apparatus: “MA-3000II” manufactured by NITTO SEIKI Co., Ltd., attaching speed: 10 mm/min, attaching pressure: 0.15 MPa, stage temperature at the time of attachment: 40° C.). Further, the wafer was subjected to dicing. The dicing was performed in a full-cut manner so that the resultant chips were each of a 10-mm square size.

Dicing conditions were as described below.
Dicing apparatus: “DFD-6361” manufactured by DISCO Corporation
Dicing ring: 2-8-1 (manufactured by DISCO Corporation)
Dicing speed: 80 mm/sec
Dicing blade (Z1): “2050HEDD” manufactured by DISCO Corporation
Dicing blade (Z2): “2050HEBB” manufactured by DISCO Corporation
Dicing blade rotation speed (Z1):
   40,000 rpm
Dicing blade rotation speed (Z2):
   40,000 rpm
Blade height (Z1): 0.170 mm (depending on the thickness of the semiconductor wafer (0.170 mm for a wafer thickness of 75 μm))
Blade height (Z2): 0.085 mm
Cutting mode: A mode/step cut
Wafer chip size: 10.0-mm square

Next, the expanding step of expanding each dicing die-bonding film to establish a predetermined interval between the respective chips was performed.

Further, the evaluation for the pickup property was performed by picking up the semiconductor chips from the base material side of each dicing die-bonding film by a push-up mode with a needle.

Specifically, 400 semiconductor chips were continuously picked up, and the case where both success ratios when the pickup was performed under Conditions A and Conditions B shown in Table 1 were 100% was evaluated as ⊚, the case where the success ratio when the pickup was performed under Conditions A was 100% and the success ratio when the pickup was performed under Conditions B was not 100% was evaluated as ∘, and the case where both the success ratios under Conditions A and Conditions B were not 100% was evaluated as x.

### <Evaluation for Pickup Property (for Examples 3-1 to 3-6, Examples 4-1 to 4-6, Comparative Examples 3-1 and 3-2, and Comparative Examples 4-1 and 4-2)>

Pickup was performed with each of dicing die-bonding films in the respective examples and comparative examples according to the following procedure after the dicing of a semiconductor wafer had been performed. Then, the respective dicing die-bonding films were evaluated for their pickup properties.

The backside of the semiconductor wafer (having a diameter of 8 inches and a thickness of 0.6 mm) was polished (grinding apparatus: “DFG-8560” manufactured by DISCO Corporation), and the resultant mirror wafer having a thickness of 0.075 mm was used as a workpiece.

After a separator had been released from a dicing die-bonding film, the above-mentioned mirror wafer was attached onto the die-bonding film by being crimped with a roll at 40° C. (attaching apparatus: “MA-3000II” manufactured by NITTO SEIKI Co., Ltd., attaching speed: 10 mm/min, attaching pressure: 0.15 MPa, stage temperature at the time of attachment: 40° C.). Further, the wafer was subjected to dicing. The dicing was performed in a full-cut manner so that the resultant chips were each of a 10-mm square size.

Dicing conditions were as described below.
Dicing apparatus: “DFD-6361” manufactured by DISCO Corporation
Dicing ring: 2-8-1 (manufactured by DISCO Corporation)
Dicing speed: 80 mm/sec
Dicing blade (Z1): “2050HEDD” manufactured by DISCO Corporation
Dicing blade (Z2): “2050HEBB” manufactured by DISCO Corporation
Dicing blade rotation speed (Z1):
   40,000 rpm
Dicing blade rotation speed (Z2):
   40,000 rpm
Blade height (Z1): 0.170 mm (depending on the thickness of the semiconductor wafer (0.170 mm for a wafer thickness of 75 μm))
Blade height (Z2): 0.085 mm
Cutting mode: A mode/step cut
Wafer chip size: 10.0-mm square

Next, each dicing die-bonding film was irradiated with UV light. The UV light was applied from a polyolefin film side (ultraviolet (UV) irradiation apparatus: “UM-810” manufactured by NITTO SEIKI Co., Ltd., UV irradiation cumulative light quantity: 300 mJ/cm²).

Next, the expanding step of expanding each dicing die-bonding film to establish a predetermined interval between the respective chips was performed.

Further, the evaluation for the pickup property was performed by picking up the semiconductor chips from the base material side of each dicing die-bonding film by a push-up mode with a needle.

Specifically, 400 semiconductor chips were continuously picked up, and the case where both success ratios when the pickup was performed under Conditions A and Conditions B shown in Table 1 were 100% was evaluated as ⊚, the case where the success ratio when the pickup was performed under Conditions A was 100% and the success ratio when the pickup was performed under Conditions B was not 100% was evaluated as ∘, and the case where both the success ratios under Conditions A and Conditions B were not 100% was evaluated as x.

TABLE 1

| | Conditions A | Conditions B |
|---|---|---|
| Needle | Total length 10 mm, Diameter 0.7 mm, Acute | |
| | angle 15 deg, Tip R 350 μm | |
| Number of needles | 9 | 5 |
| (needles) | | |
| Needle push-up amount | 350 | 250 |
| (μm) | | |
| Needle push-up speed | 5 | 5 |
| (mm/sec) | | |
| Collet retention time | 200 | 200 |
| (msec) | | |
| Expansion (mm) | 3 | 3 |

### <Measurement of Acid Value>

An evaluation for an acid value was performed in conformity with JIS K 0070-1992 (potentiometric titration).

Specifically, 100 ml of acetone were added to about 3 g of a pressure-sensitive adhesive in a dried pressure-sensitive adhesive layer, and then the mixture was stirred so that the pressure-sensitive adhesive was dissolved. 25 Milliliters of water were added to the solution, and then the mixture was stirred. The solution was titrated with a 0.05-mol/l solution of potassium hydroxide. The number of milligrams of potassium hydroxide needed for neutralizing 1 g of the sample was defined as an acid value.

<Measurement of Pressure-Sensitive Adhesive Strength Before Irradiation with Active Energy Ray>

A pressure-sensitive adhesive sheet (measuring 20 mm by 100 mm) was crimped onto the surface of a silicon mirror wafer (manufactured by Shin-Etsu Semiconductor, tradename “CZN<100>2.5-3.5” (4 inches)) under a 23° C. atmosphere by reciprocating a hand roller once.

After a lapse of 30 minutes at 23° C., a strength needed for releasing the sheet was measured (180° release, tension speed: 300 mm/min, under a 23° C.×50% RH environment).

<Measurement of Pressure-Sensitive Adhesive Strength after Irradiation with Active Energy Ray>

A pressure-sensitive adhesive sheet (measuring 20 mm by 100 mm) was crimped onto the surface of a silicon mirror wafer (manufactured by Shin-Etsu Semiconductor, tradename “CZN<100>2.5-3.5” (4 inches)) under a 23° C. atmosphere by reciprocating a hand roller once.

After a lapse of 30 minutes at 23° C., UV light (light quantity: 450 mJ/cm²) was applied from a pressure-sensitive adhesive sheet surface side with an ultraviolet irradiation apparatus (tradename “UM-810”: manufactured by NITTO SEIKI Co., Ltd.). After that, a strength needed for releasing the sample was measured (180° release, tension speed: 300 mm/min, under a 23° C.×50% RH environment).

### <Measurement of Increase in Amount of Organic Substance Contamination on Wafer>

A pressure-sensitive adhesive sheet piece was attached (attaching pressure: 0.25 MPa, attaching speed: 2.4 m/min) to an aluminum-deposited wafer (12 atomic % to 13 atomic %) with a tape-attaching machine (tradename “DR8500-II”: manufactured by NITTO SEIKI Co., Ltd.). After having been left to stand at 40° C. for 1 day, the pressure-sensitive adhesive sheet piece was irradiated with UV light (light quantity: 450 mJ/cm²) from a pressure-sensitive adhesive sheet surface side. After that, the pressure-sensitive adhesive sheet piece was released (releasing speed: 8 m/min, releasing angle: 180°) with a tape-releasing machine (tradename “HR8500-II”: manufactured by NITTO SEIKI Co., Ltd.), and then the amount of an organic substance transferred onto the wafer was measured with an ESCA (tradename “model 5400”: manufactured by ULVAC-PHI, Inc.).

The wafer to which no sheet was attached was similarly analyzed, and was evaluated for the amount in which the organic substance was transferred on the basis of an increase in amount of detected carbon atoms in an atomic % unit.

### Example 1-1

### Production of Dicing Film

90 Parts of 2-ethylhexyl acrylate (hereinafter referred to as “2EHA”), 10 parts of acrylic acid (hereinafter referred to as “AA”), 0.2 part of benzoyl peroxide, and 150 parts of ethyl acetate were loaded into a reaction vessel provided with a condenser, a nitrogen-introducing pipe, a temperature gauge, and a stirring apparatus, and then the mixture was subjected to a polymerization treatment in a stream of nitrogen at 61° C. for 6 hours. Thus, an acrylic polymer A was obtained.

12.8 Parts (95 mol % with respect to AA) of 2-vinyl-2-oxazoline (hereinafter referred to as “VO”) were added to the acrylic polymer A, and then the mixture was subjected to an addition reaction treatment in a stream of air at 50° C. for 48 hours. Thus, an acrylic polymer A′ was obtained. The acrylic polymer A′ had a glass transition temperature of −49° C.

Next, 4 parts of a polyisocyanate compound (tradename “Coronate L,” manufactured by Nippon Polyurethane Industry Co., Ltd.) and 5 parts of a photopolymerization initiator (tradename “IRGACURE 651,” manufactured by Ciba Specialty Chemicals) were added to 100 parts of the acrylic polymer A′. Thus, a pressure-sensitive adhesive solution was prepared.

The above-mentioned pressure-sensitive adhesive solution was applied onto the surface of a PET release liner subjected to a silicone treatment, and was then cross-linked under heating at 120° C. for 2 minutes. Thus, a pressure-sensitive adhesive layer having a thickness of 10 μm was formed.

Next, a polyolefin film having a thickness of 100 μm was attached to the surface of the pressure-sensitive adhesive layer.

After the resultant had been stored at 50° C. for 24 hours, a portion to which a die-bonding film was to be attached was irradiated with UV light. Thus, a dicing film was produced. The UV light was applied from the polyolefin film side (ultraviolet (UV) irradiation apparatus: “UM-810” manufactured by NITTO SEIKI Co., Ltd., UV irradiation cumulative light quantity: 300 mJ/cm²).

### <Production of Die-Bonding Film>

59 Parts of an epoxy resin 1 (“EPICOAT 1004” manufactured by JER), 53 parts of an epoxy resin 2 (“EPICOAT 827” manufactured by JER), 121 parts of a phenol resin (“MILEX XLC-4L” manufactured by Mitsui Chemicals, Inc.), and 222 parts of spherical silica (“SO-25R” manufactured by Admatechs Company Limited) were added to 100 parts of an acrylic acid ester-based polymer mainly formed of ethyl acrylate and methyl methacrylate (“Paracron W-197CM” manufactured by Negami Chemical Industrial Co., Ltd.), and then the mixture was dissolved in methyl ethyl ketone. Thus, an adhesive composition solution having a concentration of 23.6 wt % was obtained.

The resultant adhesive composition solution was applied as a release liner (separator) onto a release-treated film formed of a silicone release-treated polyethylene terephthalate film having a thickness of 38 μm, and was then dried at 130° C. for 2 minutes. Thus, a die-bonding film having a thickness of 25 μm was produced.

### <Production of Dicing Die-Bonding Film>

A dicing die-bonding film (1-1) was produced by transferring the die-bonding film onto the pressure-sensitive adhesive layer side in the dicing film.

The resultant dicing die-bonding film (1-1) was subjected to various evaluations. Table 2 shows the results.

It should be noted that the meaning of each abbreviation described in Table 2 is as described below.
2EHA: 2-ethylhexyl acrylate
i-OA: isooctyl acrylate
BA: n-butyl acrylate
AA: acrylic acid
VO: 2-vinyl-2-oxazoline

### Examples 1-2 to 1-5

Dicing die-bonding films (1-2) to (1-5) were each produced in the same manner as in Example 1-1 except that the composition and the contents were changed to those shown in Table 2.

The resultant dicing die-bonding films (1-2) to (1-5) were subjected to various evaluations. Table 2 shows the results.

### Comparative Examples 1-1 and 1-2

Dicing die-bonding films (C1-1) and (C1-2) were each produced in the same manner as in Example 1-1 except that the composition and the contents were changed to those shown in Table 2.

The resultant dicing die-bonding films (C1-1) and (C1-2) were subjected to various evaluations. Table 2 shows the results.

TABLE 2

| | Example | Example | Example | Example | Example | Comparative | Comparative |
|---|---|---|---|---|---|---|---|
| | 1-1 | 1-2 | 1-3 | 1-4 | 1-5 | Example 1-1 | Example 1-2 |
| i-OA | — | 90 | — | — | — | — | — |
| (Part(s) by weight) | | | | | | | |
| 2EHA | 90 | — | 90 | 70 | 50 | 90 | 100 |
| (Part(s) by weight) | | | | | | | |
| BA | — | — | — | 20 | 40 | — | — |
| (Part(s) by weight) | | | | | | | |
| AA | 10 | 10 | 10 | 10 | 10 | 10 | — |
| (Part(s) by weight) | | | | | | | |
| VO | 12.8 | 12.8 | 9.4 | 12.8 | 12.8 | — | 12.8 |
| (Part(s) by weight) | | | | | | | |
| Molar ratio of VO with respect | 95 | 95 | 70 | 95 | 95 | — | — |
| to AA (%) | | | | | | | |
| Glass transition temperature | −49 | −49 | −51 | −46 | −43 | −61 | −59 |
| (° C.) | | | | | | | |
| Pickup property | ⊚ | ⊚ | ◯ | ⊚ | ◯ | X | X |
| Acid value | 3.2 | 3.2 | 20.5 | 3.2 | 3.2 | 77 | 0.2 |

As shown in Table 2, the dicing die-bonding film of the present invention is found to have good pickup property. That is, it is found that the dicing die-bonding film of the present invention can express good retention for a semiconductor wafer upon its dicing, and good releasability with which semiconductor chips after the dicing can be released from the base material together with the die-bonding film in a balanced manner. In addition, the dicing die-bonding film of the present invention is found to be free of any adverse effect on an environment because the film does not use any tin-based catalyst used in a conventional pressure-sensitive adhesive. Further, it is found that the dicing die-bonding film of the present invention is free of any adverse effect on an environment or a human body because the remaining of a volatile substance in its pressure-sensitive adhesive layer can be suppressed, and that the film can be easily handled.

### Example 2-1

### Production of Dicing Film

87 Parts of 2-ethylhexyl acrylate (hereinafter referred to as “2EHA”), 12 parts of 2-vinyl-2-oxazoline (hereinafter referred to as “VO”), 1 part of 2-hydroxyethyl acrylate (hereinafter referred to as “HEA”), 0.2 part of benzoyl peroxide, and 150 parts of ethyl acetate were loaded into a reaction vessel provided with a condenser, a nitrogen-introducing pipe, a temperature gauge, and a stirring apparatus, and then the mixture was subjected to a polymerization treatment in a stream of nitrogen at 61° C. for 6 hours. Thus, an acrylic polymer A was obtained.

8.5 Parts (95 mol % with respect to VO) of acrylic acid (hereinafter referred to as “AA”) were added to the acrylic polymer A, and then the mixture was subjected to an addition reaction treatment in a stream of air at 50° C. for 48 hours. Thus, an acrylic polymer A′ was obtained. The acrylic polymer A′ had a glass transition temperature of −50° C.

Next, 4 parts of a polyisocyanate compound (tradename “Coronate L,” manufactured by Nippon Polyurethane Industry Co., Ltd.) and 5 parts of a photopolymerization initiator (tradename “IRGACURE 651,” manufactured by Ciba Specialty Chemicals) were added to 100 parts of the acrylic polymer A′. Thus, a pressure-sensitive adhesive solution was prepared.

The above-mentioned pressure-sensitive adhesive solution was applied onto the surface of a PET release liner subjected to a silicone treatment, and was then cross-linked under heating at 120° C. for 2 minutes. Thus, a pressure-sensitive adhesive layer having a thickness of 10 μm was formed.

Next, a polyolefin film having a thickness of 100 μm was attached to the surface of the pressure-sensitive adhesive layer.

After the resultant had been stored at 50° C. for 24 hours, a portion to which a die-bonding film was to be attached was irradiated with UV light. Thus, a dicing film was produced. The UV light was applied from the polyolefin film side (ultraviolet (UV) irradiation apparatus: “UM-810” manufactured by NITTO SEIKI Co., Ltd., UV irradiation cumulative light quantity: 300 mJ/cm²).

### <Production of Die-Bonding Film>

59 Parts of an epoxy resin 1 (“EPICOAT 1004” manufactured by JER), 53 parts of an epoxy resin 2 (“EPICOAT 827” manufactured by JER), 121 parts of a phenol resin (“MILEX XLC-4L” manufactured by Mitsui Chemicals, Inc.), and 222 parts of spherical silica (“SO-25R” manufactured by Admatechs Company Limited) were added to 100 parts of an acrylic acid ester-based polymer mainly formed of ethyl acrylate and methyl methacrylate (“Paracron W-197CM” manufactured by Negami Chemical Industrial Co., Ltd.), and then the mixture was dissolved in methyl ethyl ketone. Thus, an adhesive composition solution having a concentration of 23.6 wt % was obtained.

The resultant adhesive composition solution was applied as a release liner (separator) onto a release-treated film formed of a silicone release-treated polyethylene terephthalate film having a thickness of 38 μm, and was then dried at 130° C. for 2 minutes. Thus, a die-bonding film having a thickness of 25 μm was produced.

### <Production of Dicing Die-Bonding Film>

A dicing die-bonding film (2-1) was produced by transferring the die-bonding film onto the pressure-sensitive adhesive layer side in the dicing film.

The resultant dicing die-bonding film (2-1) was subjected to various evaluations. Table 3 shows the results.

It should be noted that the meaning of each abbreviation described in Table 3 is as described below.
2EHA: 2-ethylhexyl acrylate
i-OA: isooctyl acrylate
BA: n-butyl acrylate
HEA: 2-hydroxyethyl acrylate
AA: acrylic acid
M5600: acrylic photocurable resin (“Aronix M5600” manufactured by TOAGOSEI CO., LTD.)
VO: 2-vinyl-2-oxazoline

### Examples 2-2 to 2-6

Dicing die-bonding films (2-2) to (2-6) were each produced in the same manner as in Example 2-1 except that the composition and the contents were changed to those shown in Table 3.

The resultant dicing die-bonding films (2-2) to (2-6) were subjected to various evaluations. Table 3 shows the results.

### Comparative Examples 2-1 and 2-2

Dicing die-bonding films (C2-1) and (C2-2) were each produced in the same manner as in Example 2-1 except that the composition and the contents were changed to those shown in Table 3.

The resultant dicing die-bonding films (C2-1) and (C2-2) were subjected to various evaluations. Table 3 shows the results.

TABLE 3

| | Example | Example | Example | Example | Example | Example | Comparative | Comparative |
|---|---|---|---|---|---|---|---|---|
| | 2-1 | 2-2 | 2-3 | 2-4 | 2-5 | 2-6 | Example 2-1 | Example 2-2 |
| i-OA | — | 87 | — | — | — | — | — | — |
| (Part(s) by weight) | | | | | | | | |
| 2EHA | 87 | — | 87 | 87 | 57 | 47 | 99 | 87 |
| (Part(s) by weight) | | | | | | | | |
| BA | — | — | — | — | 30 | 40 | — | — |
| (Part(s) by weight) | | | | | | | | |
| HEA | 1 | 1 | 1 | 1 | 1 | 1 | 1 | 1 |
| (Part(s) by weight) | | | | | | | | |
| VO | 12 | 12 | 12 | 12 | 12 | 12 | — | 12 |
| (Part(s) by weight) | | | | | | | | |
| AA | 8.5 | 8.5 | — | 6.2 | 8.5 | 8.5 | 8.5 | — |
| (Part(s) by weight) | | | | | | | | |
| M5600 | — | — | 20.3 | — | — | — | — | — |
| (Part(s) by weight) | | | | | | | | |
| Molar ratio of AA or M5600 | 95 | 95 | 95 | 70 | 95 | 95 | — | — |
| with respect to VO (%) | | | | | | | | |
| Glass transition temperature | −50 | −50 | −48 | −51 | −45 | −43 | −61 | −57 |
| (° C.) | | | | | | | | |
| Pickup property | ⊚ | ⊚ | ⊚ | ◯ | ⊚ | ◯ | X | X |
| Acid value | 0.2 | 0.2 | 0.2 | 0.2 | 0.2 | 0.2 | 0.2 | 0.2 |

As shown in Table 3, the dicing die-bonding film of the present invention is found to have good pickup property. That is, it is found that the dicing die-bonding film of the present invention can express good retention for a semiconductor wafer upon its dicing, and good releasability with which semiconductor chips after the dicing can be released from the base material together with the die-bonding film in a balanced manner. In addition, the dicing die-bonding film of the present invention is found to be free of any adverse effect on an environment because the film does not use any tin-based catalyst used in a conventional pressure-sensitive adhesive. Further, it is found that the dicing die-bonding film of the present invention is free of any adverse effect on an environment or a human body because the remaining of a volatile substance in its pressure-sensitive adhesive layer can be suppressed, and that the film can be easily handled.

### Example 3-1

### Production of Dicing Film

90 Parts of 2-ethylhexyl acrylate (hereinafter referred to as “2EHA”), 10 parts of acrylic acid (hereinafter referred to as “AA”), 0.2 part of benzoyl peroxide, and 150 parts of ethyl acetate were loaded into a reaction vessel provided with a condenser, a nitrogen-introducing pipe, a temperature gauge, and a stirring apparatus, and then the mixture was subjected to a polymerization treatment in a stream of nitrogen at 61° C. for 6 hours. Thus, an acrylic polymer A was obtained.

12.8 Parts (95 mol % with respect to AA) of 2-vinyl-2-oxazoline (hereinafter referred to as “VO”) were added to the acrylic polymer A, and then the mixture was subjected to an addition reaction treatment in a stream of air at 50° C. for 48 hours. Thus, an acrylic polymer A′ was obtained. The acrylic polymer A′ had a glass transition temperature of −49° C.

Next, 4 parts of a polyisocyanate compound (tradename “Coronate L,” manufactured by Nippon Polyurethane Industry Co., Ltd.) and 5 parts of a photopolymerization initiator (tradename “IRGACURE 651,” manufactured by Ciba Specialty Chemicals) were added to 100 parts of the acrylic polymer A′. Thus, a pressure-sensitive adhesive solution was prepared.

The above-mentioned pressure-sensitive adhesive solution was applied onto the surface of a PET release liner subjected to a silicone treatment, and was then cross-linked under heating at 120° C. for 2 minutes. Thus, a pressure-sensitive adhesive layer having a thickness of 10 μm was formed.

Next, a polyolefin film having a thickness of 100 μm was attached to the surface of the pressure-sensitive adhesive layer.

The resultant was stored at 50° C. for 24 hours, to thereby obtain a dicing film.

### <Production of Die-Bonding Film>

59 Parts of an epoxy resin 1 (“EPICOAT 1004” manufactured by JER), 53 parts of an epoxy resin 2 (“EPICOAT 827” manufactured by JER), 121 parts of a phenol resin (“MILEX XLC-4L” manufactured by Mitsui Chemicals, Inc.), and 222 parts of spherical silica (“SO-25R” manufactured by Admatechs Company Limited) were added to 100 parts of an acrylic acid ester-based polymer mainly formed of ethyl acrylate and methyl methacrylate (“Paracron W-197CM” manufactured by Negami Chemical Industrial Co., Ltd.), and then the mixture was dissolved in methyl ethyl ketone. Thus, an adhesive composition solution having a concentration of 23.6 wt % was obtained.

The resultant adhesive composition solution was applied as a release liner (separator) onto a release-treated film formed of a silicone release-treated polyethylene terephthalate film having a thickness of 38 μm, and was then dried at 130° C. for 2 minutes. Thus, a die-bonding film having a thickness of 25 μm was produced.

### <Production of Dicing Die-Bonding Film>

A dicing die-bonding film (3-1) was produced by transferring the die-bonding film onto the pressure-sensitive adhesive layer side in the dicing film.

The resultant dicing die-bonding film (3-1) was subjected to various evaluations. Table 4 shows the results.

It should be noted that the meaning of each abbreviation described in Table 4 is as described below.
2EHA: 2-ethylhexyl acrylate
i-OA: isooctyl acrylate
BA: n-butyl acrylate
AA: acrylic acid
VO: 2-vinyl-2-oxazoline

### Examples 3-2 to 3-5

Dicing die-bonding films (3-2) to (3-5) were each produced in the same manner as in Example 3-1 except that the composition and the contents were changed to those shown in Table 4.

The resultant dicing die-bonding films (3-2) to (3-5) were subjected to various evaluations. Table 4 shows the results.

### Comparative Examples 3-1 and 3-2

Dicing die-bonding films (C3-1) and (C3-2) were each produced in the same manner as in Example 3-1 except that the composition and the contents were changed to those shown in Table 4.

The resultant dicing die-bonding films (C3-1) and (C3-2) were subjected to various evaluations. Table 4 shows the results.

TABLE 4

| | Example | Example | Example | Example | Example | Comparative | Comparative |
|---|---|---|---|---|---|---|---|
| | 3-1 | 3-2 | 3-3 | 3-4 | 3-5 | Example 3-1 | Example 3-2 |
| i-OA | — | — | 90 | — | — | — | — |
| (Part(s) by weight) | | | | | | | |
| 2EHA | 90 | 70 | — | 90 | 60 | 100 | 90 |
| (Part(s) by weight) | | | | | | | |
| BA | — | 20 | — | — | 30 | — | — |
| (Part(s) by weight) | | | | | | | |
| AA | 10 | 10 | 10 | 10 | 10 | — | 10 |
| (Part(s) by weight) | | | | | | | |
| VO | 12.8 | 12.8 | 12.8 | 9.4 | 12.8 | 12.8 | — |
| (Part(s) by weight) | | | | | | | |
| Molar ratio of VO with respect | 95 | 95 | 95 | 70 | 95 | — | — |
| to AA (%) | | | | | | | |
| Glass transition temperature | −49 | −46 | −49 | −51 | −47 | −59 | −61 |
| (° C.) | | | | | | | |
| Pickup property | ⊚ | ◯ | ⊚ | ◯ | ◯ | X | X |
| Acid value | 3.2 | 3.2 | 3.2 | 20.5 | 3.2 | 0.2 | 77 |

As shown in Table 4, the dicing die-bonding film of the present invention is found to have good pickup property. That is, it is found that the dicing die-bonding film of the present invention can express good retention for a semiconductor wafer upon its dicing, and good releasability with which semiconductor chips after the dicing can be released from the base material together with the die-bonding film in a balanced manner. In addition, the dicing die-bonding film of the present invention is found to be free of any adverse effect on an environment because the film does not use any tin-based catalyst used in a conventional pressure-sensitive adhesive. Further, it is found that the dicing die-bonding film of the present invention is free of any adverse effect on an environment or a human body because the remaining of a volatile substance in its pressure-sensitive adhesive layer can be suppressed, and that the film can be easily handled.

### Example 4-1

### Production of Dicing Film

87 Parts of 2-ethylhexyl acrylate (hereinafter referred to as “2EHA”), 12 parts of 2-vinyl-2-oxazoline (hereinafter referred to as “VO”), 1 part of 2-hydroxyethyl acrylate (hereinafter referred to as “HEA”), 0.2 part of benzoyl peroxide, and 150 parts of ethyl acetate were loaded into a reaction vessel provided with a condenser, a nitrogen-introducing pipe, a temperature gauge, and a stirring apparatus, and then the mixture was subjected to a polymerization treatment in a stream of nitrogen at 61° C. for 6 hours. Thus, an acrylic polymer A was obtained.

8.5 Parts (95 mol % with respect to VO) of acrylic acid (hereinafter referred to as “AA”) were added to the acrylic polymer A, and then the mixture was subjected to an addition reaction treatment in a stream of air at 50° C. for 48 hours. Thus, an acrylic polymer A′ was obtained. The acrylic polymer A′ had a glass transition temperature of −50° C.

Next, 4 parts of a polyisocyanate compound (tradename “Coronate L,” manufactured by Nippon Polyurethane Industry Co., Ltd.) and 5 parts of a photopolymerization initiator (tradename “IRGACURE 651,” manufactured by Ciba Specialty Chemicals) were added to 100 parts of the acrylic polymer A′. Thus, a pressure-sensitive adhesive solution was prepared.

The above-mentioned pressure-sensitive adhesive solution was applied onto the surface of a PET release liner subjected to a silicone treatment, and was then cross-linked under heating at 120° C. for 2 minutes. Thus, a pressure-sensitive adhesive layer having a thickness of 10 μm was formed.

Next, a polyolefin film having a thickness of 100 μm was attached to the surface of the pressure-sensitive adhesive layer.

The resultant was stored at 50° C. for 24 hours, to thereby obtain a dicing film.

### <Production of Die-Bonding Film>

59 Parts of an epoxy resin 1 (“EPICOAT 1004” manufactured by JER), 53 parts of an epoxy resin 2 (“EPICOAT 827” manufactured by JER), 121 parts of a phenol resin (“MILEX XLC-4L” manufactured by Mitsui Chemicals, Inc.), and 222 parts of spherical silica (“SO-25R” manufactured by Admatechs Company Limited) were added to 100 parts of an acrylic acid ester-based polymer mainly formed of ethyl acrylate and methyl methacrylate (“Paracron W-197CM” manufactured by Negami Chemical Industrial Co., Ltd.), and then the mixture was dissolved in methyl ethyl ketone. Thus, an adhesive composition solution having a concentration of 23.6 wt % was obtained.

The resultant adhesive composition solution was applied as a release liner (separator) onto a release-treated film formed of a silicone release-treated polyethylene terephthalate film having a thickness of 38 μm, and was then dried at 130° C. for 2 minutes. Thus, a die-bonding film having a thickness of 25 μm was produced.

### <Production of Dicing Die-Bonding Film>

A dicing die-bonding film (4-1) was produced by transferring the die-bonding film onto the pressure-sensitive adhesive layer side in the dicing film.

The resultant dicing die-bonding film (4-1) was subjected to various evaluations. Table 5 shows the results.

It should be noted that the meaning of each abbreviation described in Table 5 is as described below.
2EHA: 2-ethylhexyl acrylate
i-OA: isooctyl acrylate
BA: n-butyl acrylate
HEA: 2-hydroxyethyl acrylate
AA: acrylic acid
M5600: acrylic photocurable resin (“Aronix M5600” manufactured by TOAGOSEI CO., LTD.)
VO: 2-vinyl-2-oxazoline

### Examples 4-2 to 4-6

Dicing die-bonding films (4-2) to (4-6) were each produced in the same manner as in Example 4-1 except that the composition and the contents were changed to those shown in Table 5.

The resultant dicing die-bonding films (4-2) to (4-6) were subjected to various evaluations. Table 5 shows the results.

### Comparative Examples 4-1 and 4-2

Dicing die-bonding films (C4-1) and (C4-2) were each produced in the same manner as in Example 4-1 except that the composition and the contents were changed to those shown in Table 5.

The resultant dicing die-bonding films (C4-1) and (C4-2) were subjected to various evaluations. Table 5 shows the results.

TABLE 5

| | Example | Example | Example | Example | Example | Example | Comparative | Comparative |
|---|---|---|---|---|---|---|---|---|
| | 4-1 | 4-2 | 4-3 | 4-4 | 4-5 | 4-6 | Example 4-1 | Example 4-2 |
| i-OA | — | 87 | — | — | — | — | — | — |
| (Part(s) by weight) | | | | | | | | |
| 2EHA | 87 | — | 87 | 65 | 87 | 57 | 99 | 87 |
| (Part(s) by weight) | | | | | | | | |
| BA | — | — | — | 22 | — | 30 | — | — |
| (Part(s) by weight) | | | | | | | | |
| HEA | 1 | 1 | 1 | 1 | 1 | 1 | 1 | 1 |
| (Part(s) by weight) | | | | | | | | |
| VO | 12 | 12 | 12 | 12 | 12 | 12 | — | 12 |
| (Part(s) by weight) | | | | | | | | |
| AA | 8.5 | 8.5 | — | 8.5 | 6.2 | 8.5 | 8.5 | — |
| (Part(s) by weight) | | | | | | | | |
| M5600 | — | — | 20.3 | — | — | — | — | — |
| (Part(s) by weight) | | | | | | | | |
| Molar ratio of AA or M5600 | 95 | 95 | 95 | 95 | 70 | 95 | — | — |
| with respect to VO (%) | | | | | | | | |
| Glass transition temperature | −50 | −50 | −48 | −46 | −51 | −45 | −61 | −57 |
| (° C.) | | | | | | | | |
| Pickup property | ⊚ | ⊚ | ⊚ | ◯ | ◯ | ◯ | X | X |
| Acid value | 0.2 | 0.2 | 0.2 | 0.2 | 0.2 | 0.2 | 0.2 | 0.2 |

As shown in Table 5, the dicing die-bonding film of the present invention is found to have good pickup property. That is, it is found that the dicing die-bonding film of the present invention can express good retention for a semiconductor wafer upon its dicing, and good releasability with which semiconductor chips after the dicing can be released from the base material together with the die-bonding film in a balanced manner. In addition, the dicing die-bonding film of the present invention is found to be free of any adverse effect on an environment because the film does not use any tin-based catalyst used in a conventional pressure-sensitive adhesive. Further, it is found that the dicing die-bonding film of the present invention is free of any adverse effect on an environment or a human body because the remaining of a volatile substance in its pressure-sensitive adhesive layer can be suppressed, and that the film can be easily handled.

### Example 5-1

90 Parts of 2-ethylhexyl acrylate (hereinafter referred to as “2EHA”), 10 parts of acrylic acid (hereinafter referred to as “AA”), 0.2 part of benzoyl peroxide, and 150 parts of ethyl acetate were loaded into a reaction vessel provided with a condenser, a nitrogen-introducing pipe, a temperature gauge, and a stirring apparatus, and then the mixture was subjected to a polymerization treatment in a stream of nitrogen at 61° C. for 6 hours. Thus, an acrylic polymer A was obtained.

12.1 Parts (90 mol % with respect to AA) of 2-vinyl-2-oxazoline (hereinafter referred to as “VO”) were added to the acrylic polymer A, and then the mixture was subjected to an addition reaction treatment in a stream of air at 50° C. for 48 hours. Thus, an acrylic polymer A′ was obtained. The acrylic polymer A′ had a glass transition temperature of −49° C.

Next, 3 parts of a polyisocyanate compound (tradename “Coronate L,” manufactured by Nippon Polyurethane Industry Co., Ltd.) and 5 parts of a photopolymerization initiator (tradename “IRGACURE 651,” manufactured by Ciba Specialty Chemicals) were added to 100 parts of the acrylic polymer A′. Thus, a pressure-sensitive adhesive solution was prepared.

The above-mentioned pressure-sensitive adhesive solution was applied onto the silicone release-treated surface of a polyester film subjected to a silicone release treatment (thickness: 50 μm) so as to have a thickness after its drying of 30 μm, and was then dried at 120° C. for 3 minutes. Thus, a pressure-sensitive adhesive layer was formed.

An ethylene-vinyl acetate copolymer film (thickness: 115 μm) whose surface had been subjected to an oxidation treatment by a corona discharge mode was attached to the pressure-sensitive adhesive surface of the pressure-sensitive adhesive layer so that the pressure-sensitive adhesive layer was transferred. Thus, a pressure-sensitive adhesive sheet (5-1) was produced.

The resultant pressure-sensitive adhesive sheet (5-1) was subjected to various evaluations. Table 6 shows the results.

It should be noted that the meaning of each abbreviation described in Table 6 is as described below.
2EHA: 2-ethylhexyl acrylate
EA: ethyl acrylate
BA: n-butyl acrylate
AA: acrylic acid
VO: 2-vinyl-2-oxazoline

### Examples 5-2 to 5-6

Pressure-sensitive adhesive sheets (5-2) to (5-6) were each produced in the same manner as in Example 5-1 except that the composition and the contents were changed to those shown in Table 6.

The resultant pressure-sensitive adhesive sheets (5-2) to (5-6) were subjected to various evaluations. Table 6 shows the results.

### Comparative Examples 5-1 and 5-2

Pressure-sensitive adhesive sheets (C5-1) and (C5-2) were each produced in the same manner as in Example 5-1 except that the composition and the contents were changed to those shown in Table 6.

The resultant pressure-sensitive adhesive sheets (C5-1) and (C5-2) were subjected to various evaluations. Table 6 shows the results.

TABLE 6

| | Example | Example | Example | Example | Example | Example | Comparative | Comparative |
|---|---|---|---|---|---|---|---|---|
| | 5-1 | 5-2 | 5-3 | 5-4 | 5-5 | 5-6 | Example 5-1 | Example 5-2 |
| BA | — | 90 | — | 82 | 90 | 90 | 90 | 90 |
| (Part(s) by weight) | | | | | | | | |
| 2EHA | 90 | — | 50 | — | — | — | — | — |
| (Part(s) by weight) | | | | | | | | |
| EA | — | — | 42 | 10 | — | — | 10 | — |
| (Part(s) by weight) | | | | | | | | |
| AA | 10 | 10 | 8 | 8 | 10 | 10 | — | 10 |
| (Part(s) by weight) | | | | | | | | |
| VO | 12.1 | 12.1 | 10.2 | 10.2 | 4.0 | 6.7 | 10.2 | — |
| (Part(s) by weight) | | | | | | | | |
| Molar ratio of VO with respect | 90 | 90 | 95 | 95 | 30 | 50 | — | — |
| to AA (%) | | | | | | | | |
| Glass transition temperature | −49 | −35 | −34 | −35 | −42 | −39 | −52 | −45 |
| (° C.) | | | | | | | | |
| Pressure-sensitive adhesive | 2.8 | 3.4 | 3.3 | 3.5 | 3.6 | 3.5 | 0.32 | 3.7 |
| strength before irradiation | | | | | | | | |
| with active energy ray | | | | | | | | |
| (N/20 mm) | | | | | | | | |
| Pressure-sensitive adhesive | 0.14 | 0.13 | 0.13 | 0.12 | 0.17 | 0.14 | 1.5 | 3.6 |
| strength after irradiation | | | | | | | | |
| with active energy ray | | | | | | | | |
| (N/20 mm) | | | | | | | | |

As shown in Table 6, it is found that the active energy ray-curable pressure-sensitive adhesive for re-release of the present invention can largely change its pressure-sensitive adhesiveness before and after irradiation with an active energy ray, and can express high pressure-sensitive adhesiveness before the irradiation with the active energy ray and express high releasability after the irradiation with the active energy ray. In addition, the active energy ray-curable pressure-sensitive adhesive for re-release of the present invention is found to be free of any adverse effect on an environment because the pressure-sensitive adhesive does not use any tin-based catalyst used in a conventional active energy ray-curable pressure-sensitive adhesive for re-release. Further, it is found that the active energy ray-curable pressure-sensitive adhesive for re-release of the present invention is free of any adverse effect on an environment or a human body because the remaining of a volatile substance in the pressure-sensitive adhesive can be suppressed, and that the pressure-sensitive adhesive can be easily handled.

### Example 6-1

89 Parts of 2-ethylhexyl acrylate (hereinafter referred to as “2EHA”), 10 parts of 2-vinyl-2-oxazoline (hereinafter referred to as “VO”), 1 part of 2-hydroxyethyl acrylate (hereinafter referred to as “HEA”), 0.2 part of benzoyl peroxide, and 150 parts of ethyl acetate were loaded into a reaction vessel provided with a condenser, a nitrogen-introducing pipe, a temperature gauge, and a stirring apparatus, and then the mixture was subjected to a polymerization treatment in a stream of nitrogen at 61° C. for 6 hours. Thus, an acrylic polymer A was obtained.

7.1 Parts (95 mol % with respect to VO) of acrylic acid (hereinafter referred to as “AA”) were added to the acrylic polymer A, and then the mixture was subjected to an addition reaction treatment in a stream of air at 50° C. for 48 hours. Thus, an acrylic polymer A′ was obtained. The acrylic polymer A′ had a glass transition temperature of −53° C.

Next, 3 parts of a polyisocyanate compound (tradename “Coronate L,” manufactured by Nippon Polyurethane Industry Co., Ltd.) and 5 parts of a photopolymerization initiator (tradename “IRGACURE 651,” manufactured by Ciba Specialty Chemicals) were added to 100 parts of the acrylic polymer A′. Thus, a pressure-sensitive adhesive solution was prepared.

The above-mentioned pressure-sensitive adhesive solution was applied onto the silicone release-treated surface of a polyester film subjected to a silicone release treatment (thickness: 50 μm) so as to have a thickness after its drying of 30 μm, and was then dried at 120° C. for 3 minutes. Thus, a pressure-sensitive adhesive layer was formed.

An ethylene-vinyl acetate copolymer film (thickness: 115 μm) whose surface had been subjected to an oxidation treatment by a corona discharge mode was attached to the pressure-sensitive adhesive surface of the pressure-sensitive adhesive layer so that the pressure-sensitive adhesive layer was transferred. Thus, a pressure-sensitive adhesive sheet (6-1) was produced.

The resultant pressure-sensitive adhesive sheet (6-1) was subjected to various evaluations. Table 7 shows the results.

It should be noted that the meaning of each abbreviation described in Table 7 is as described below.
2EHA: 2-ethylhexyl acrylate
EA: ethyl acrylate
BA: n-butyl acrylate
AA: acrylic acid
HEA: 2-hydroxyethyl acrylate
VO: 2-vinyl-2-oxazoline
M5600: acrylic photocurable resin (“Aronix M5600” manufactured by TOAGOSEI CO., LTD.)

### Examples 6-2 to 6-7

Pressure-sensitive adhesive sheets (6-2) to (6-7) were each produced in the same manner as in Example 6-1 except that the composition and the contents were changed to those shown in Table 7.

The resultant pressure-sensitive adhesive sheets (6-2) to (6-7) were subjected to various evaluations. Table 7 shows the results.

### Comparative Examples 6-1 and 6-2

Pressure-sensitive adhesive sheets (C6-1) and (C6-2) were each produced in the same manner as in Example 6-1 except that the composition and the contents were changed to those shown in Table 7.

The resultant pressure-sensitive adhesive sheets (C6-1) and (C6-2) were subjected to various evaluations. Table 7 shows the results.

TABLE 7

| | Example | Example | Example | Example | Example | Example | Example | Comparative | Comparative |
|---|---|---|---|---|---|---|---|---|---|
| | 6-1 | 6-2 | 6-3 | 6-4 | 6-5 | 6-6 | 6-7 | Example 6-1 | Example 6-2 |
| BA | — | 89 | — | — | 77 | 89 | 89 | 89 | 89 |
| (Part(s) by weight) | | | | | | | | | |
| 2EHA | 89 | — | 89 | 47 | — | — | — | — | — |
| (Part(s) by weight) | | | | | | | | | |
| EA | — | — | — | 40 | 10 | — | — | 10 | — |
| (Part(s) by weight) | | | | | | | | | |
| VO | 10 | 10 | 10 | 12 | 12 | 10 | 10 | — | 10 |
| (Part(s) by weight) | | | | | | | | | |
| HEA | 1 | 1 | 1 | 1 | 1 | 1 | 1 | 1 | 1 |
| (Part(s) by weight) | | | | | | | | | |
| AA | 7.1 | 7.1 | — | 8.6 | 8.6 | 2.2 | 3.7 | 7.1 | — |
| (Part(s) by weight) | | | | | | | | | |
| M5600 | — | — | 16.9 | — | — | — | — | — | — |
| (Part(s) by weight) | | | | | | | | | |
| Molar ratio of AA or M5600 | 95 | 95 | 95 | 96 | 96 | 30 | 50 | — | — |
| with respect to VO (%) | | | | | | | | | |
| Glass transition temperature | −53 | −39 | −52 | −31 | −32 | −43 | −42 | −46 | −44 |
| (° C.) | | | | | | | | | |
| Pressure-sensitive adhesive | 2.9 | 3.6 | 3.2 | 3.7 | 3.7 | 3.8 | 0.37 | 0.30 | 3.9 |
| strength before irradiation | | | | | | | | | |
| with active energy ray | | | | | | | | | |
| (N/20 mm) | | | | | | | | | |
| Pressure-sensitive adhesive | 0.15 | 0.14 | 0.16 | 0.14 | 0.14 | 0.21 | 0.19 | 1.2 | 3.8 |
| strength after irradiation | | | | | | | | | |
| with active energy ray | | | | | | | | | |
| (N/20 mm) | | | | | | | | | |

As shown in Table 7, it is found that the active energy ray-curable pressure-sensitive adhesive for re-release of the present invention can largely change its pressure-sensitive adhesiveness before and after irradiation with an active energy ray, and can express high pressure-sensitive adhesiveness before the irradiation with the active energy ray and express high releasability after the irradiation with the active energy ray. In addition, the active energy ray-curable pressure-sensitive adhesive for re-release of the present invention is found to be free of any adverse effect on an environment because the pressure-sensitive adhesive does not use any tin-based catalyst used in a conventional active energy ray-curable pressure-sensitive adhesive for re-release. Further, it is found that the active energy ray-curable pressure-sensitive adhesive for re-release of the present invention is free of any adverse effect on an environment or a human body because the remaining of a volatile substance in the pressure-sensitive adhesive can be suppressed, and that the pressure-sensitive adhesive can be easily handled.

### Example 7-1

200 Parts of water, 92 parts of 2-ethylhexyl acrylate (hereinafter referred to as “2EHA”), 8 parts of methacrylic acid (hereinafter referred to as “MAA”), and 2 parts of an ether sulfate-type, reactive anionic surfactant (tradename “ADEKASOAP SE-10N,” manufactured by ADEKA CORPORATION) were emulsified with an emulsifying machine. The resultant emulsion solution was charged into a reaction vessel provided with a condenser, a nitrogen-introducing pipe, a temperature gauge, and a stirring apparatus, and then the air in the vessel was replaced with nitrogen for 1 hour under stirring.

Hereinafter, an inner bath temperature during polymerization was controlled to 25° C.

An aqueous solution of ascorbic acid formed of 0.1 part of aqueous hydrogen peroxide (containing 30 wt % of hydrogen peroxide), 0.05 part of ascorbic acid, and 10 parts of water (the amount ratio of each component was a ratio with respect to 100 parts of all the above-mentioned monomer components) was prepared.

1 Milliliter of the above-mentioned aqueous solution of ascorbic acid was added to the above-mentioned reaction vessel, and then polymerization was initiated. After a lapse of 5 hours from the initiation of the polymerization, the remaining aqueous solution of ascorbic acid was dropped over 2 hours, and then the reaction was aged over an additional two hours.

After that, the resultant was neutralized with 10% ammonia water so as to have a pH of 8. Thus, an acrylic polymer A was obtained.

8.1 Parts (90 mol % with respect to MAA) of 2-vinyl-2-oxazoline (hereinafter referred to as “VO”) were added to 100 parts of the acrylic polymer A, and then the mixture was subjected to an addition reaction treatment in a stream of air at 50° C. for 48 hours. Thus, an acrylic polymer A′ was obtained. The acrylic polymer A′ had a glass transition temperature of −54° C.

Next, 0.2 part of an epoxy-based cross-linking agent (tradename “TETRAD-C,” manufactured by Mitsubishi Gas Chemical Company Inc.) and 2 parts of a photopolymerization initiator (1-[4-(2-hydroxyethoxy)-phenyl]-2-hydroxy-2-methyl-1-propane-1-on, tradename “IRGACURE 2959,” manufactured by Ciba Specialty Chemicals) were added to 100 parts of the acrylic polymer A′. Thus, a pressure-sensitive adhesive solution was prepared.

The above-mentioned pressure-sensitive adhesive solution was applied onto the silicone release-treated surface of a polyester film subjected to a silicone release treatment (thickness: 50 μm) so as to have a thickness after its drying of 30 μm, and was then dried at 120° C. for 3 minutes. Thus, a pressure-sensitive adhesive layer was formed.

An ethylene-vinyl acetate copolymer film (thickness: 115 μm) whose surface had been subjected to an oxidation treatment by a corona discharge mode was attached to the pressure-sensitive adhesive surface of the pressure-sensitive adhesive layer so that the pressure-sensitive adhesive layer was transferred. Thus, a pressure-sensitive adhesive sheet (7-1) was produced.

The resultant pressure-sensitive adhesive sheet (7-1) was subjected to various evaluations. Table 8 shows the results.

It should be noted that the meaning of each abbreviation described in Table 8 is as described below.
2EHA: 2-ethylhexyl acrylate
EA: ethyl acrylate
BA: n-butyl acrylate
MAA: methacrylic acid
VO: 2-vinyl-2-oxazoline
SE10N: reactive anionic surfactant (tradename “ADEKASOAP SE-10N,” manufactured by ADEKA CORPORATION)
LA16: anionic surfactant (tradename “HITENOL LA-16,” manufactured by Kao Corporation)

### Examples 7-2 to 7-6

Pressure-sensitive adhesive sheets (7-2) to (7-6) were each produced in the same manner as in Example 7-1 except that the composition and the contents were changed to those shown in Table 8.

The resultant pressure-sensitive adhesive sheets (7-2) to (7-6) were subjected to various evaluations. Table 8 shows the results.

### Comparative Examples 7-1 and 7-2

Pressure-sensitive adhesive sheets (C7-1) and (C7-2) were each produced in the same manner as in Example 7-1 except that the composition and the contents were changed to those shown in Table 8.

The resultant pressure-sensitive adhesive sheets (C7-1) and (C7-2) were subjected to various evaluations. Table 8 shows the results.

TABLE 8

| | Example | Example | Example | Example | Example | Example | Comparative | Comparative |
|---|---|---|---|---|---|---|---|---|
| | 7-1 | 7-2 | 7-3 | 7-4 | 7-5 | 7-6 | Example 7-1 | Example 7-2 |
| BA | — | 92 | — | — | — | — | — | — |
| (Part(s) by weight) | | | | | | | | |
| 2EHA | 92 | — | 50 | 92 | 92 | 92 | 92 | 92 |
| (Part(s) by weight) | | | | | | | | |
| EA | — | — | 42 | — | — | — | — | 8 |
| (Part(s) by weight) | | | | | | | | |
| MAA | 8 | 8 | 8 | 8 | 8 | 8 | 8 | — |
| (Part(s) by weight) | | | | | | | | |
| SE10N | 2 | 2 | 2 | 2 | 2 | — | 2 | — |
| (Part(s) by weight) | | | | | | | | |
| LA16 | — | — | — | — | — | 2 | — | — |
| (Part(s) by weight) | | | | | | | | |
| VO | 8.1 | 8.1 | 8.1 | 2.7 | 4.5 | 8.1 | — | 8.1 |
| (Part(s) by weight) | | | | | | | | |
| Molar ratio of VO with respect | 90 | 90 | 90 | 30 | 50 | 90 | — | — |
| to MAA (%) | | | | | | | | |
| Glass transition temperature | −54 | −40 | −35 | −59 | −57 | −54 | −61 | −66 |
| (° C.) | | | | | | | | |
| Pressure-sensitive adhesive | 2.1 | 2.3 | 2.2 | 2.2 | 2.3 | 2.2 | 2.3 | 0.4 |
| strength before irradiation | | | | | | | | |
| with active energy ray | | | | | | | | |
| (N/20 mm) | | | | | | | | |
| Pressure-sensitive adhesive | 0.17 | 0.18 | 0.19 | 0.22 | 0.20 | 0.17 | 2.4 | 1.1 |
| strength after irradiation | | | | | | | | |
| with active energy ray | | | | | | | | |
| (N/20 mm) | | | | | | | | |
| Increase in amount of organic | 3.7 | 3.5 | 3.5 | 4.1 | 4.0 | 8.4 | 4.2 | 10.5 |
| substance contamination on | | | | | | | | |
| wafer (atomic %) | | | | | | | | |

As shown in Table 8, the active energy ray-curable pressure-sensitive adhesive for re-release of the present invention is an aqueous pressure-sensitive adhesive, and hence the pressure-sensitive adhesive is free of any adverse effect on an environment or a human body, and can be easily handled as compared with a solvent-based pressure-sensitive adhesive. Further, it is found that the active energy ray-curable pressure-sensitive adhesive for re-release of the present invention can largely change its pressure-sensitive adhesiveness before and after irradiation with an active energy ray, and can express high pressure-sensitive adhesiveness before the irradiation with the active energy ray and express high releasability after the irradiation with the active energy ray. In addition, the active energy ray-curable pressure-sensitive adhesive for re-release of the present invention is found to be free of any adverse effect on an environment because the pressure-sensitive adhesive does not use any tin-based catalyst used in a conventional active energy ray-curable pressure-sensitive adhesive for re-release. Further, it is found that the active energy ray-curable pressure-sensitive adhesive for re-release of the present invention is free of any adverse effect on an environment or a human body because the remaining of a volatile substance in the pressure-sensitive adhesive can be suppressed, and that the pressure-sensitive adhesive can be easily handled.

### Example 8-1

200 Parts of water, 92 parts of 2-ethylhexyl acrylate (hereinafter referred to as “2EHA”), 7 parts of 2-vinyl-2-oxazoline (hereinafter referred to as “VO”), 1 part of diacetone acrylamide (hereinafter referred to as “DAAM”), and 2 parts of an ether sulfate-type, reactive anionic surfactant (tradename “ADEKASOAP SE-10N,” manufactured by ADEKA CORPORATION) were emulsified with an emulsifying machine. The resultant emulsion solution was charged into a reaction vessel provided with a condenser, a nitrogen-introducing pipe, a temperature gauge, and a stirring apparatus, and then the air in the vessel was replaced with nitrogen for 1 hour under stirring.

Hereinafter, an inner bath temperature during polymerization was controlled to 25° C.

An aqueous solution of ascorbic acid formed of 0.1 part of aqueous hydrogen peroxide (containing 30 wt % of hydrogen peroxide), 0.05 part of ascorbic acid, and 10 parts of water (the amount ratio of each component was a ratio with respect to 100 parts of all the above-mentioned monomer components) was prepared.

1 Milliliter of the above-mentioned aqueous solution of ascorbic acid was added to the above-mentioned reaction vessel, and then polymerization was initiated. After a lapse of 5 hours from the initiation of the polymerization, the remaining aqueous solution of ascorbic acid was dropped over 2 hours, and then the reaction was aged over an additional two hours.

After that, the resultant was neutralized with 10% ammonia water so as to have a pH of 8. Thus, an acrylic polymer A was obtained.

4.7 Parts (90 mol % with respect to VO) of acrylic acid (hereinafter referred to as “AA”) were added to 100 parts of the acrylic polymer A, and then the mixture was subjected to an addition reaction treatment in a stream of air at 50° C. for 48 hours. Thus, an acrylic polymer A′ was obtained. The acrylic polymer A′ had a glass transition temperature of −57° C.

Next, 0.5 part of a adipic dihydrazide and 2 parts of a photopolymerization initiator (1-[4-(2-hydroxyethoxy)-phenyl]-2-hydroxy-2-methyl-1-propane-1-on, tradename “IRGACURE 2959,” manufactured by Ciba Specialty Chemicals) were added to 100 parts of the acrylic polymer A′. Thus, a pressure-sensitive adhesive solution was prepared.

The above-mentioned pressure-sensitive adhesive solution was applied onto the silicone release-treated surface of a polyester film subjected to a silicone release treatment (thickness: 50 μm) so as to have a thickness after its drying of 30 μm, and was then dried at 120° C. for 3 minutes. Thus, a pressure-sensitive adhesive layer was formed.

An ethylene-vinyl acetate copolymer film (thickness: 115 μm) whose surface had been subjected to an oxidation treatment by a corona discharge mode was attached to the pressure-sensitive adhesive surface of the pressure-sensitive adhesive layer so that the pressure-sensitive adhesive layer was transferred. Thus, a pressure-sensitive adhesive sheet (8-1) was produced.

The resultant pressure-sensitive adhesive sheet (8-1) was subjected to various evaluations. Table 9 shows the results.

It should be noted that the meaning of each abbreviation described in Table 9 is as described below.
2EHA: 2-ethylhexyl acrylate
EA: ethyl acrylate
BA: n-butyl acrylate
AA: acrylic acid
VO: 2-vinyl-2-oxazoline
SE10N: reactive anionic surfactant (tradename “ADEKASOAP SE-10N,” manufactured by ADEKA CORPORATION)
LA16: anionic surfactant (tradename “HITENOL LA-16,” manufactured by Kao Corporation)

### Examples 8-2 to 8-6

Pressure-sensitive adhesive sheets (8-2) to (8-6) were each produced in the same manner as in Example 8-1 except that the composition and the contents were changed to those shown in Table 9.

The resultant pressure-sensitive adhesive sheets (8-2) to (8-6) were subjected to various evaluations. Table 9 shows the results.

### Comparative Examples 8-1 and 8-2

Pressure-sensitive adhesive sheets (C8-1) and (C8-2) were each produced in the same manner as in Example 8-1 except that the composition and the contents were changed to those shown in Table 9.

The resultant pressure-sensitive adhesive sheets (C8-1) and (C8-2) were subjected to various evaluations. Table 9 shows the results.

TABLE 9

| | Example | Example | Example | Example | Example | Example | Comparative | Comparative |
|---|---|---|---|---|---|---|---|---|
| | 8-1 | 8-2 | 8-3 | 8-4 | 8-5 | 8-6 | Example 8-1 | Example 8-2 |
| BA | — | 92 | — | — | — | — | — | — |
| (Part(s) by weight) | | | | | | | | |
| 2EHA | 92 | — | 50 | 92 | 92 | 92 | 92 | 92 |
| (Part(s) by weight) | | | | | | | | |
| EA | — | — | 42 | — | — | — | — | 7 |
| (Part(s) by weight) | | | | | | | | |
| DAAM | 1 | 1 | 1 | 1 | 1 | 1 | 1 | 1 |
| (Part(s) by weight) | | | | | | | | |
| VO | 7 | 7 | 7 | 7 | 7 | 7 | 7 | — |
| (Part(s) by weight) | | | | | | | | |
| SE10N | 2 | 2 | 2 | 2 | 2 | — | 2 | 2 |
| (Part(s) by weight) | | | | | | | | |
| LA16 | — | — | — | — | — | 2 | — | — |
| (Part(s) by weight) | | | | | | | | |
| AA | 4.7 | 4.7 | 4.7 | 1.6 | 2.6 | 4.7 | — | 4.7 |
| (Part(s) by weight) | | | | | | | | |
| Molar ratio of AA with respect | 90 | 90 | 90 | 30 | 50 | 90 | — | — |
| to VO (%) | | | | | | | | |
| Glass transition temperature | −57 | −43 | −39 | −60 | −59 | −57 | −61 | −61 |
| (° C.) | | | | | | | | |
| Pressure-sensitive adhesive | 2.4 | 2.6 | 2.5 | 2.6 | 2.6 | 2.6 | 2.6 | 0.5 |
| strength before irradiation | | | | | | | | |
| with active energy ray | | | | | | | | |
| (N/20 mm) | | | | | | | | |
| Pressure-sensitive adhesive | 0.18 | 0.17 | 0.17 | 0.19 | 0.18 | 0.18 | 2.7 | 1.0 |
| strength after irradiation | | | | | | | | |
| with active energy ray | | | | | | | | |
| (N/20 mm) | | | | | | | | |
| Increase in amount of organic | 3.9 | 3.8 | 3.8 | 4.3 | 4.2 | 8.7 | 4.5 | 8.9 |
| substance contamination on | | | | | | | | |
| wafer (atomic %) | | | | | | | | |

As shown in Table 9, the active energy ray-curable pressure-sensitive adhesive for re-release of the present invention is an aqueous pressure-sensitive adhesive, and hence the pressure-sensitive adhesive is free of any adverse effect on an environment or a human body, and can be easily handled as compared with a solvent-based pressure-sensitive adhesive. Further, it is found that the active energy ray-curable pressure-sensitive adhesive for re-release of the present invention can largely change its pressure-sensitive adhesiveness before and after irradiation with an active energy ray, and can express high pressure-sensitive adhesiveness before the irradiation with the active energy ray and express high releasability after the irradiation with the active energy ray. In addition, the active energy ray-curable pressure-sensitive adhesive for re-release of the present invention is found to be free of any adverse effect on an environment because the pressure-sensitive adhesive does not use any tin-based catalyst used in a conventional active energy ray-curable pressure-sensitive adhesive for re-release. Further, it is found that the active energy ray-curable pressure-sensitive adhesive for re-release of the present invention is free of any adverse effect on an environment or a human body because the remaining of a volatile substance in the pressure-sensitive adhesive can be suppressed, and that the pressure-sensitive adhesive can be easily handled.

The active energy ray-curable pressure-sensitive adhesive for re-release of the present invention can be suitably used in, for example, the dicing of a workpiece (such as a semiconductor wafer) upon production of a semiconductor apparatus.

The dicing die-bonding film of the present invention can be suitably used in, for example, the dicing of a workpiece (such as a semiconductor wafer) upon production of a semiconductor apparatus.

What is claimed is:

1. A dicing die-bonding film, comprising:
a base material;
a dicing film having a pressure-sensitive adhesive layer on the base material; and
a die-bonding film provided on the pressure-sensitive adhesive layer,
wherein:
the pressure-sensitive adhesive layer contains one of an active energy ray-curable pressure-sensitive adhesive for re-release and a cured product of the pressure-sensitive adhesive, wherein the active energy ray-curable pressure-sensitive adhesive for re-release comprises an active energy ray-curable polymer (P), wherein the polymer (P) comprises one of a polymer obtained by causing a carboxyl group-containing polymer (P3) and an oxazoline group-containing monomer (m3) to react with each other, and a polymer obtained by causing an oxazoline group-containing polymer (P4) and a carboxyl group-containing monomer (m2) to react with each other; and
the die-bonding film contains an epoxy resin.

2. A dicing die-bonding film according to claim 1, wherein the carboxyl group-containing polymer (P3) comprises a polymer (P1) constructed of monomer components containing an acrylic acid ester (m1) as a main monomer and the carboxyl group-containing monomer (m2).

3. A dicing die-bonding film according to claim 1, wherein the oxazoline group-containing polymer (P4) comprises a polymer (P2) constructed of monomer components containing an acrylic acid ester (m1) as a main monomer and the oxazoline group-containing monomer (m3).

4. A dicing die-bonding film according to claim 1, wherein the carboxyl group-containing monomer (m2) comprises at least one kind selected from the group consisting of (meth)acrylic acid and a carboxyalkyl (meth)acrylate.

5. A dicing die-bonding film according to claim 1, wherein the oxazoline group-containing monomer (m3) comprises at least one kind selected from the group consisting of 2-vinyl-2-oxazoline, 4-methyl-2-vinyl-2-oxazoline, 5-methyl-2-vinyl-2-oxazoline, 2-vinyl-4,4-dimethyl-2-oxazoline, 2-isopropenyl-2-oxazoline, 4-methyl-2-isopropenyl-2-oxazoline, 5-methyl-2-isopropenyl-2-oxazoline, and 2-isopropenyl-4,4-dimethyl-2-oxazoline.

6. A dicing die-bonding film according to claim 1, wherein the polymer (P) has a glass transition temperature of −70° C. to −10° C.
